(19) United States
(12) Patent Application Publication
(10) Pub. No.: US 2010/0084687 A1
(43) Pub. Date: Apr. 8, 2010

(54) ALUMINUM GALLIUM NITRIDE/GALLIUM NITRIDE HIGH ELECTRON MOBILITY TRANSISTORS

(75) Inventors: Jing Chen, Hong Kong (CN); Maojun Wang, Hong Kong (CN)

Correspondence Address: TUROCY & WATSON, LLP, 127 Public Square, 57th Floor, Key Tower, CLEVELAND, OH, 44114, US

(73) Assignee: THE HONG KONG UNIVERSITY OF SCIENCE AND TECHNOLOGY, Hong Kong (CN)

(21) Appl. No.: 12/558,242

(22) Filed: Sep. 11, 2009

Related U.S. Application Data
(60) Provisional application No. 61/136,793, filed on Oct. 3, 2008.

(51) Int. Cl. H01L 29/778; H01L 21/335

(52) U.S. Cl. 257/194; 438/172; 257/76; 257/E29.246; 257/E21.403

(57) ABSTRACT

Structures, devices and methods are provided for creating enhanced back barriers that improve the off-state breakdown and blocking characteristics in aluminum gallium nitride AlGaN/GaN high electron mobility transistors (HEMTs). In one aspect, selective fluorine ion implantation is employed when developing HEMTs to create the enhanced back barrier structures. By creating higher energy barriers at the back of the two-dimensional electron gas channel in the unintentionally doped GaN buffer, higher off-state breakdown voltage is advantageously provided and blocking capability is enhanced, while allowing for convenient and cost-effective post-epitaxial growth fabrication. Further non-limiting embodiments are provided that illustrate the advantages and flexibility of the disclosed structures.

### FIELD OF THE INVENTION

This application claims priority to U.S. Provisional Patent Application Ser. No. 61/136,793, filed on Oct. 3, 2008, and entitled METHOD OF CREATING BACK BARRIER, AND ENHANCING THE OFF-STATE BREAKDOWN AND BLOCKING CAPABILITY IN AlGaN/GaN HEMT BY FLUORINE ION IMPLANTATION, the entirety of which is hereby incorporated by reference.

### FIELD OF THE INVENTION

The subject disclosure is directed to field effect transistors and, more specifically, to structures, devices, and methods for creating a back barrier and enhancing off-state breakdown and blocking characteristics in Aluminum Gallium Nitride/Gallium Nitride (AlGaN/GaN) High Electron Mobility Transistors (HEMTs) by fluorine ion implantation.

### BACKGROUND OF THE INVENTION

High Electron Mobility Transistors (HEMTs), also called heterostructure field-effect transistors (HFETs) or modulation-doped field-effect transistors (MODFETs), are field effect transistors typically incorporating a junction between two materials with different band gaps, e.g., a heterojunction, as the channel instead of a doped region. HEMTs use high mobility electrons generated by a heterojunction comprised of a highly-doped wider-bandgap n-type donor-supply layer, or unintentionally doped Aluminum-Gallium-Nitride (AlGaN), for example, and a non-doped narrower-bandgap layer with little or no intentional dopants, e.g., Gallium-Nitride (GaN).

For example, electrons generated in an n-type donor-supply layer can drop into the non-doped narrower-bandgap channel at the heterojunction to form a thin depleted n-type donor-supply sub-layer and narrower-bandgap channel, due to the heterojunction created by different band-gap materials forming an electron potential well in the conduction band on the non-doped side of the heterojunction. In the framework of AlGaN/GaN heterostructures, there is often no dopant required in the AlGaN layer due to the strong spontaneous and piezoelectric polarization effect in such systems. For example, electrons from surface donors can be swept into the GaN channel by the intrinsic polarization induced electric field. In this instance, the electrons can move quickly without colliding with any impurities, due to the unintentionally doped (e.g., not intentionally doped) layer's relative lack of impurities or dopants, from which the electrons cannot escape. The net result of such a heterojunction is to create a very thin layer of highly mobile conducting electrons with very high concentration or density, giving the channel very low resistivity. This layer is known as a two-dimensional electron gas (2DEG). As can be expected in field-effect transistor (FET), voltage applied to the gate alters the conductivity of this layer to form transistor structures.

One kind of high-electron mobility transistor (HEMT) including Gallium Nitride is known as an Aluminum Gallium Nitride/Gallium Nitride (AlGaN/GaN) HEMT, or an AlGaN/GaN HEMT. Typically, AlGaN/GaN HEMTs can be fabricated by growing crystalline films of GaN, AlGaN, etc. on a substrate (e.g., sapphire, silicon (Si)(111), silicon carbide (SiC), etc.) through an epitaxial crystal growth method (e.g., metal organic chemical vapor deposition (MOCVD), molecular beam epitaxy (MBE), etc.) and processing the epitaxial substrate thus grown, to form the desired structures.

Recently, AlGaN/GaN HEMTs have received attention for their ability to operate at high voltage and high current levels, which results in enhanced high-power performance, as a benefit of the inherent high-density 2DEG, high electron mobility, and high critical breakdown electric field. As a consequence, the wide bandgap AlGaN/GaN HEMTs are emerging as excellent candidates for next-generation radio-frequency (RF) and microwave power amplifiers. One important operational and design parameter of field-effect transistors (FETs) generally and HEMTs in particular is the off-state breakdown voltage (BV_{off}), because it determines the maximum output power for class A operation.

However, reported off-state breakdown voltage values still remain significantly below the theoretical limit for such devices. For instance, current injected from the source to the drain, resulting from unintentional n-type background doping (e.g., due to intrinsic nitrogen vacancies or oxygen impurities) in the unintentionally doped GaN (i-GaN) buffer layer, has been shown to be one of the main factors that limit the breakdown voltage in practical devices. It has been shown that drain induced barrier lowering (DIBL) in the GaN buffer layer worsens at greater depths from the 2DEG channel, for example, due to the low barrier of the GaN buffer layer. As a result, it is expected that electrons can be injected from the source to the high-field region through the buffer and initiate impact ionization in the channel at large drain bias and cause the premature three-terminal off-state breakdown of the device before gate breakdown.

While a general reduction in n-type background doping in the unintentionally doped GaN buffer layer has been attempted, such efforts have typically proved to be difficult and commercially unviable. Additionally, intentional incorporation of deep acceptor levels in the GaN buffer layer by doping with carbon (C) or iron (Fe) traps electrons and causes current collapse in the HEMT device as well as large hysteresis current-voltage (I-V) output characteristics of the devices, while also potentially causing permanent contamination of the growth system. In addition, these acceptors may cause device instability, especially at high drain voltage. It is thus desired to improve the breakdown voltage characteristics in practical HEMT devices.

### SUMMARY OF THE INVENTION

The following presents a simplified summary of the specification in order to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

In various embodiments, enhanced back barrier (EBB) structures and devices are provided that improve the off-state breakdown and blocking characteristics in Group III-Nitride HEMTs in general, and AlGaN/GaN HEMTs in particular, by creating higher energy barriers at the back of the 2DEG channel in the unintentionally doped GaN buffer. Accordingly, various embodiments effectively increase and enhance the back barrier in the GaN buffer layer and enhance the off-state breakdown voltage characteristics in the provided AlGaN/GaN HEMT structures and devices.

In one non-limiting embodiment, a HEMT comprises a Schottky gate controlled 2DEG channel, an ohmic source contact and an ohmic drain contact. Advantageously, fluorine ion implantation can be performed prior to the gate metallization of the device after lithography, according to an aspect. As a result, the enhanced back barrier is self aligned with the gate metal.

In other embodiments, post-growth methodologies are provided for fabricating EBB HEMT heterostructures according to various aspects of the disclosed subject matter. The provided structures and devices can be created according to aspects of the disclosed subject matter by selectively implanting fluorine ions in developing structures (e.g., post-epitaxial growth). Advantageously, the described fluorine ion implantation operation is made available by commercial ion implantation equipment providers.

Further, one or more embodiments of HEMT heterostructures are described that incorporate an EBB layer or region comprised of implanted fluorine ions located substantially below the prospective gate location of developing EBB HEMT heterostructures. For example, various embodiments can implement an EBB region or layer comprised of implanted fluorine ions having a peak concentration located slightly below the heterojunction or interface with respect to the design or prospective location of a HEMT gate.

Negatively charged fluorine ions can also be introduced into the electronic devices to increase the local potential barrier, according to further aspects of the disclosed subject matter. As a non-limiting example, the fluorine treated locations or regions can be in the area of the source-gate access region, gate-drain drift region, source region, drain region, and the gate region. As a further example, fluorine ions can be introduced into the barrier layer and the buffer layer.

Thus, in further non-limiting embodiments, the provided structures can be combined with Low Density Drain (LDD) fabrication methods to provide a EBB/LDD combination HEMT (e.g., an EBB/LDD HEMT) heterostructure that can further improve the electric field distribution. Further non-limiting embodiments can include an EBB layer or region such that the EBB layer or region is extended substantially to the source region to further improve source-drain isolation in the HEMT “off-state.”

In addition, according to various aspects, fluorine ions can be introduced into the devices using one or more processes including plasma treatment, plasma immersion ion implantation, and ion implantation, and can be combined with the traditional field plate techniques, including gate, source, drain and multiple field plates to further improve the breakdown voltage of electronic devices. As a further advantage, other nitride based electronic devices can employ various embodiments of the disclosed subject matter to increase the local potential barrier, including Metal Semiconductor Field Effect Transistors (MESFETs), Metal Insulator Semiconductor High Electron Mobility Transistors (MISHEMTs), Metal Insulator Semiconductor Field Effect Transistors (MISFETs), lateral field-effect rectifiers (LFETs), light emitting diodes (LEDs), and laser diodes (LDs).

These and other additional features of the disclosed subject matter are described in more detail below.

### BRIEF DESCRIPTION OF THE DRAWINGS

The devices, structures, and methodologies of the disclosed subject matter are further described with reference to the accompanying drawings in which:

FIG. 1 depicts a schematic cross section view of a conventional AlGaN/GaN HEMT, in which off-state breakdown mechanisms in AlGaN/GaN HEMTs are illustrated;

FIG. 2 depicts a schematic cross section of a conventional and an EBB AlGaN/GaN HEMT, according to an exemplary non-limiting embodiment of the disclosed subject matter;

FIG. 3 depicts an alternate schematic cross section of a conventional and an EBB AlGaN/GaN HEMT, according to an exemplary non-limiting embodiment of the disclosed subject matter, in which the EBB layer or region is more accurately depicted as a continuum of fluorine ion concentrations in the EBB rather than as sub-regions of discrete concentrations;

FIG. 4 illustrates a test configuration for three terminal off-state breakdown of AlGaN/GaN HEMTs;

FIG. 5 depicts three terminal off-state breakdown characteristics of an exemplary conventional HEMT at different gate biases;

FIG. 6 depicts a comparison of breakdown voltage at three- and two-terminal test configuration;

FIG. 7 depicts the three terminal off-state breakdown characteristics of a conventional high electron mobility transistor as measured by a typical drain-current injection measurement;

FIG. 8 depicts an exemplary non-limiting electron potential energy distribution in the GaN buffer layer as a function of relative position (X) and at different depths from the channel under an exemplary conventional AlGaN/GaN HEMT gate according to various aspects of the disclosed subject matter, in which the simulation results are depicted using the Synopsys® Santaurus simulator;

FIG. 9 depicts simulation results of off-state potential energy distribution and electric field vectors under an exemplary non-limiting gate region, according to various aspects of the disclosed subject matter, in which the simulation results are depicted using the Synopsys® Santaurus simulator;

FIGS. 10-11 depict three terminal off-state breakdown characteristics of an exemplary conventional AlGaN/GaN HEMT with different gate lengths, in which current from source and drain are depicted in FIG. 10 and the gate current is depicted in FIG. 11;

FIGS. 12-13 depict three terminal off-state breakdown characteristics of an exemplary conventional AlGaN/GaN HEMT using drain-current injection, in which drain-source voltage and gate current are depicted in FIGS. 12 and 13, respectively;

FIGS. 14-15 depict three terminal off-state breakdown characteristics of an exemplary conventional AlGaN/GaN HEMT using drain-current injection, in which drain-source voltage and gate current as a function as V_{GS} (e.g., voltage relative to the device gate and source) are depicted in FIGS. 14 and 15, respectively;

FIG. 16 depicts three terminal off-state breakdown characteristics of an exemplary fabricated HEMT at various temperatures;

FIG. 17 depicts temperature dependence of three terminal off-state breakdown voltage for an exemplary conventional AlGaN/GaN HEMT according to various aspects of the disclosed subject matter;

FIG. 18 illustrates a schematic cross section of an exemplary non-limiting embodiment of an EBB AlGaN/GaN HEMT, in which implanted fluorine ions in the GaN buffer under the channel and in the gate region form a back barrier to reduce source current injection;

FIG. 19 further illustrates a schematic cross section of an exemplary non-limiting embodiment of an enhanced back barrier AlGaN/GaN HEMT, according to various aspects of the disclosed subject matter, in which FIG. 19 depicts an exemplary embodiment as described with reference to FIGS. 2-3 and 18;

FIGS. 20-21 illustrates particular aspects of an exemplary enhancement mode AlGaN/GaN HEMT fabricated by fluorine plasma treatment and an exemplary embodiment of an enhanced back barrier HEMT using fluorine ion implantation, respectively;

FIG. 22 depicts an exemplary Secondary Ion Mass Spectroscopy (SIMS) profile of implanted fluorine ions in an exemplary non-limiting embodiment of an EBB layer or region;

FIG. 23 depicts a simulated zero bias conduction band profile of exemplary non-limiting AlGaN/GaN heterostructures before and after fluorine ion implantation;

FIG. 24 depicts capacitance-voltage (C-V) curves of exemplary AlGaN/GaN heterostructures before and after fluorine ion implantation;

FIG. 25 depicts comparison of off-state breakdown characteristics between a conventional and an EBB HEMTs using current voltage measurements;

FIG. 26 depicts a comparison of the three terminal off-state breakdown characteristics between a conventional and an exemplary non-limiting embodiment of an EBB AlGaN/GaN HEMT;

FIG. 27 depicts an exemplary non-limiting electron potential energy distribution in the GaN buffer layer as a function of relative position under an exemplary non-limiting HEMT gate according to various aspects of the disclosed subject matter;

FIG. 28 depicts simulation results of off-state potential energy distribution and electric field vectors under an exemplary non-limiting gate region, according to various aspects of the disclosed subject matter, in which the simulation results are depicted using the Synopsys® Santaurus simulator;

FIG. 29 depicts a comparison of temperature dependence of three terminal off-state breakdown voltage between a conventional and an exemplary non-limiting embodiment of an EBB AlGaN/GaN HEMT;

FIGS. 30-35 demonstrate the basic device characteristics of an EBB HEMT according to aspects of the disclosed subject matter, for which FIG. 30 depicts I-V output for a conventional AlGaN/GaN HEMT and an EBB AlGaN/GaN HEMT, respectively, FIG. 31 depicts transfer characteristics, FIGS. 32-33 depict Direct Current (DC) and pulsed I-V characteristics of exemplary silicon nitride (SiN) passivated conventional and EBB HEMTs, respectively, FIG. 34 depicts maximum current gain and maximum stable gain for the exemplary devices as a function of frequency, and FIG. 35 depicts cut-off frequencies for an exemplary conventional AlGaN/GaN HEMT and an exemplary EBB AlGaN/GaN HEMT;

FIGS. 36-41 illustrate further non-limiting embodiments, according to various aspects, and relative benefits of the disclosed embodiments, in which FIG. 36 depicts a schematic cross section of an exemplary non-limiting embodiment of an AlGaN/GaN HEMT with fluorine ions implanted to improve the off-state breakdown voltage by enhancing the back barrier and to reduce the source leakage current, FIG. 37 depicts an exemplary embodiment comprising a combination of an EBB and a LDD, where anticipated electric field distribution before and after the formation of LDD using fluorine treatment is depicted in FIG. 38, FIGS. 39-40 depict further non-limiting embodiments of EBB/LDD HEMTs, and FIG. 41 depicts a schematic cross section of an exemplary enhancement mode AlGaN/GaN HEMT with enhanced back barrier under the gate and in the region from the source to the gate edge;

FIG. 42 depicts a schematic cross section of an exemplary non-limiting embodiment of a lateral field-effect rectifier according to various aspects of the disclosed AlGaN/GaN heterostructures with EBB and LDD;

FIGS. 43-44 depict a cross section of an exemplary non-limiting AlGaN/GaN vertical heterostructure field-effect transistor with a fluorine implanted blocking layer according to various aspects of the disclosed subject matter; and

FIG. 45 depicts exemplary non-limiting methodologies for forming a back barrier region in a HEMT in accordance with aspects of the disclosed subject matter.

### DETAILED DESCRIPTION OF ILLUSTRATIVE EMBODIMENTS

### Overview

As used herein, acronyms are used to denote the following: Source (S), Drain (D), Gate (G), Current (I), Voltage (V), Breakdown Voltage (BV), Transconductance (Gₘ), L (Length, Distance, or Spacing), X (Relative Position), Ohmic Contact (O), Anode (A), and Cathode (C) or Capacitance (C) as is apparent from the context.

As described above, reported off-state breakdown voltage values for AlGaN/GaN HEMTs still remain significantly below the theoretical limit. It has been shown that the DIBL effect is significant even for micron gate length devices due to the unintentionally n-type background doping of the GaN buffer in state-of-the-art AlGaN/GaN HEMT devices.

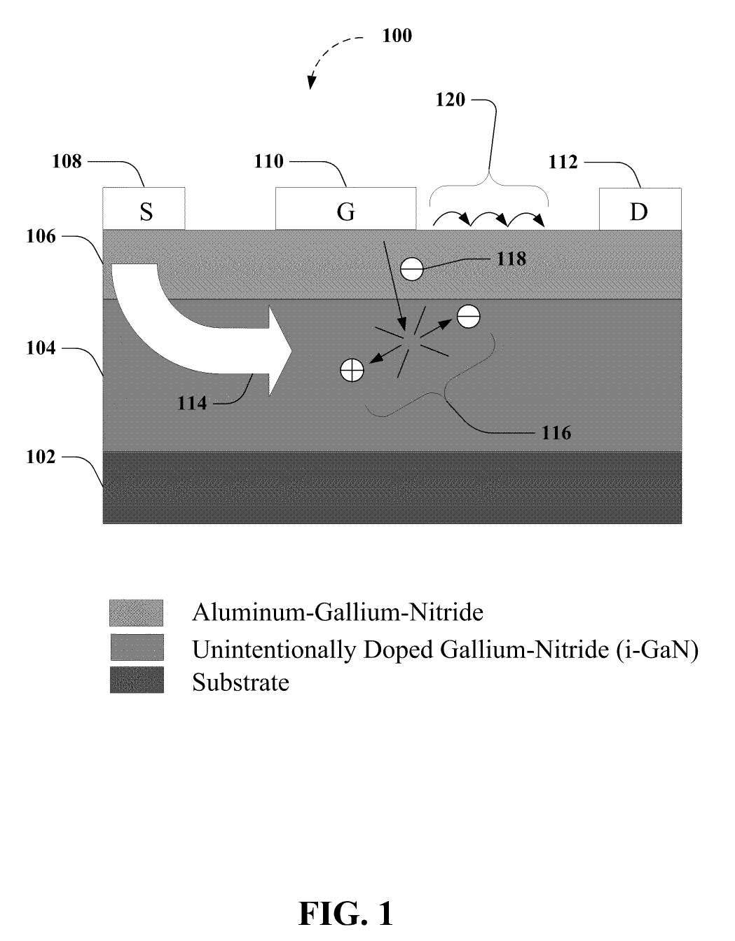

FIG. 1 depicts a schematic cross section view of a conventional AlGaN/GaN high electron mobility transistor, in which off-state breakdown mechanisms in AlGaN/GaN HEMTs are illustrated. AlGaN/GaN-HEMTs can typically be fabricated on a substrate 102 (e.g., sapphire, Silicon (Si), Silicon Carbide (SiC), etc.) by growing crystalline films of GaN 104 (e.g., buffer layer), AlGaN 106 (e.g., barrier layer), etc., for example, via an epitaxial crystal growth method (e.g., metal organic chemical vapor deposition (MOCVD), molecular beam epitaxy (MBE), etc.). Further processing the heterostructure (102/104/106) thus grown, can be performed to form the desired structures (e.g., source 108, gate 110, and drain 112, etc.).

Note that in FIG. 1, arrow 114 depicts source current injection of a typical HEMT at an off-state, which can trigger the breakdown of the HEMT at a large drain 112 bias. For example, it was found that electrons can be injected 114 from the source 108 to the drain 112 through the buffer 104 at large drain 112 bias, initiating impact ionization 116 in the channel before this process is triggered by the gate 110 injection 118. As a result, a premature three-terminal off-state breakdown can be observed in AlGaN/GaN HEMTs.

A surface hopping conduction mechanism 120 for the gate-drain leakage has been proposed, owing to an observed negative temperature coefficient in the breakdown voltage, which suggests that thermal runaway of the surface hopping may be responsible for the off-state breakdown in AlGaN/GaN HEMT. However, as the surface morphology of the AlGaN barrier 106 is improved in state-of-the-art devices, breakdown voltage exhibits positive temperature coefficients. A breakdown model has also been proposed that suggests impact ionization (e.g., inter-band or intra-band) in the channel near the drain-edge of the gate electrode 110 (e.g., where the peak electric field is located) dominates the off-state breakdown. This model exhibits a positive temperature coefficient in the breakdown voltage. However, it should be noted that for AlGaN/GaN HEMTs, when a high-quality insulating AlGaN barrier layer 106 is available, this does not favor the gate injection 118 as much as for non-AlGaN/GaN HEMTs because of a larger Schottky barrier height, a larger conduction band offset at the heterojunction interface, and an absence of doping in the barrier 106 layer.

Recently, it has been shown that source 108 injection 114 through the buffer 104 can also induce impact ionization 116 and cause a premature three-terminal breakdown in conventional AlGaN/GaN HEMTs. As described in the background, however, structures and methodologies are desired that improve breakdown voltage characteristics in practical HEMT devices. Improvement in breakdown can be achieved, for example by reducing source current injection 114 or effectively blocking source injected electrons from entering the high-field region during high voltage operation. For instance, creating higher energy barriers at the back of the 2DEG channel in the unintentionally doped GaN buffer 104 from negatively charged fluorine ions selectively located at the back side of the 2DEG channel can effectively raise the energy barrier of the GaN buffer layer 104 under the channel, which can block the current injected 114 from the source 108 to the high field region at the drain-edge of the gate electrode 110.

To these and other ends, various embodiments of the disclosed subject matter provide enhanced back barrier structures and devices (e.g., EBB HEMTs) that improve off-state breakdown and blocking characteristics in AlGaN/GaN HEMTs by creating higher energy barriers at the back of the 2DEG channel in the unintentionally doped GaN buffer 104. For instance, one or more embodiments effectively increase and enhance the back barrier in the GaN buffer layer 104, by fluorine ion implantation, and enhance the off-state breakdown voltage characteristics in AlGaN/GaN HEMT structures and devices.

The EBB is created locally under the intrinsic channel during the device fabrication, as an example, instead of the epitaxial growth stage, by fluorine ion implantation. Implanted fluorine ions act as negative ions after implantation because of the strong electronegativity of the fluorine element. Fluorine ions at the back of the 2DEG channel can increase the conduction band in the GaN layer 104 under the 2DEG channel. Consequently, source injection current 114 can be redirected around the back barrier to greater depths in the GaN buffer 104 to avoid encountering the region of high electric field. Thus, the back barrier can effectively block the current injected 114 from the source 108 to the high field region in the 2DEG channel.

In another embodiment, HEMT structures are provided that incorporate an EBB layer or region comprised of implanted fluorine ions located substantially below the prospective gate location of developing EBB HEMTs. For example, various embodiments provide an EBB region comprised of implanted fluorine ions having a peak concentration located slightly below the heterojunction with respect to the HEMT gate 110.

In further non-limiting embodiments, the provided structures are combined with low density drain fabrication methods to provide an EBB/LDD combination HEMT heterostructure that can further improve the electric field distribution before and after the formation of LDD using fluorine ion implantation treatment. In other non-limiting embodiments, structures and devices are provided with the EBB layer or region extended substantially all the way to the source region to further improve source-drain isolation in the HEMT “off-state.”

In addition, the disclosed subject matter provides methodologies for forming an EBB region in high electron mobility transistors for fabricating enhanced back barrier HEMTs, or EBB HEMTs. The provided structures and devices can be created by selectively implanting fluorine ions in developing structures (e.g., post-epitaxial growth). Besides being a post-growth process, the disclosed methodologies are compatible with current AlGaN/GaN HEMT fabrication processes. In one aspect, the described fluorine ion implantation operation is made available by commercial ion implantation equipment providers. Thus, it can be appreciated that process characteristics such as implantation depth and height of back barrier can be precisely controlled by the selection of appropriate ion implant energy and implantation time in the ion implanter. In another aspect, ion implantation allows localized potential modulation not achievable by methods such as an epitaxy approach.

As used herein, the term heterojunction is intended to include an interface that occurs between two layers or regions of dissimilar crystalline semiconducting materials, where in many instances, such semiconducting materials have unequal band gaps. The term heterostructure is intended to include one or more heterojunctions, and sometimes includes adjacent layers or structures as suggested by the context, and can include interstitial layers that are formed intentionally (e.g., crystal seed layers, etc.) or unintentionally (e.g., process contaminants, natural impurities, surface deficiencies, surface morphology changes, etc.). The term unintentionally doped (e.g., not intentionally doped) refers to the lack of intentionally placed dopants in semiconducting materials, but whose semiconductor characteristics may result from process contaminants, subsequent or antecedent processes, etc. (e.g., due to intrinsic nitrogen vacancies or oxygen impurities, etc.). Prospective location and design location, as it refers to the location of a completed HEMT device's components (e.g., source, drain, gate), is used to denote that a location for future fabrication of the device's components is determined, but the components may not yet be fabricated.

Additionally, variations of the disclosed embodiments as suggested by the disclosed structures and methodologies are intended to be encompassed within the scope of the subject matter disclosed herein. Furthermore, the various embodiments of the structures, devices, and methodologies of the disclosed subject matter can include variations in the location of the EBB region or layer and/or the concentration profile of implanted ions used to create the EBB region or layer, etc.

### Exemplary Non-Limiting AlGaN/GaN EBB HEMTs

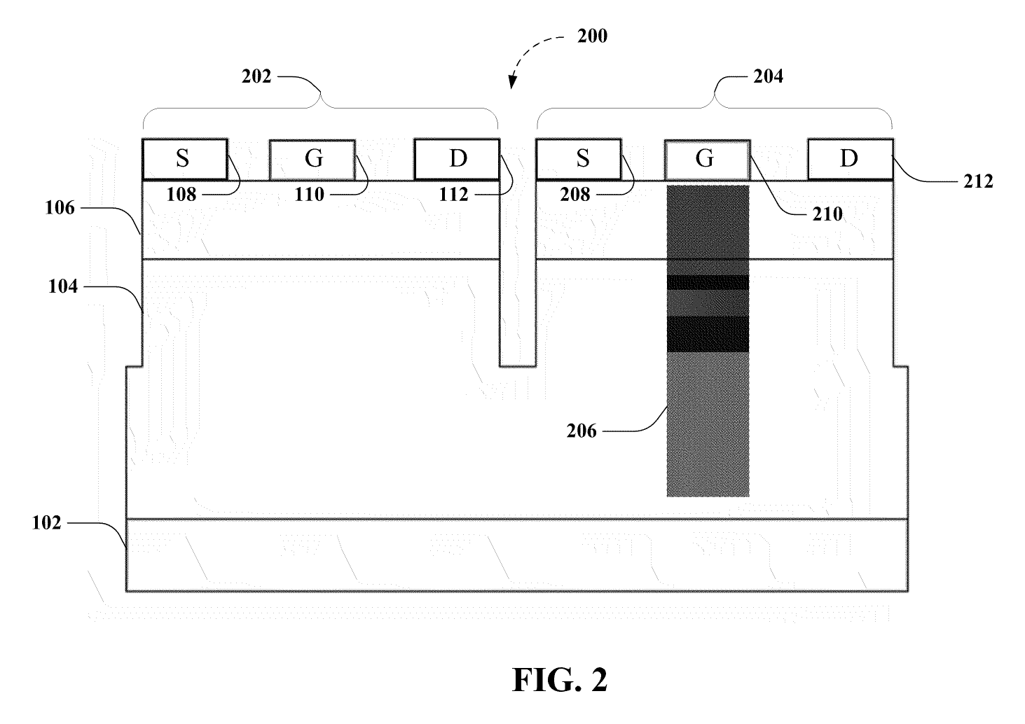

FIG. 2 depicts a schematic cross section 200 of a conventional AlGaN/GaN HEMT 202 and an EBB AlGaN/GaN HEMT 204 with fluorine ion implantation, according to an exemplary non-limiting embodiment.

As described above, AlGaN/GaN-HEMTs can typically be fabricated by growing crystalline films of GaN 104, AlGaN 106, etc., on a substrate 102 (e.g., sapphire, Si, SiC, etc.), for example, via an epitaxial crystal growth method (e.g., MOCVD, MBE, etc.) and processing the epitaxial substrate (102/104/106) thus grown, to form the desired structures. For example, as an exemplary non-limiting illustration of an AlGaN/GaN HEMT heterostructure, the cross-section 200 can comprise 2 micrometers (μm) of unintentionally doped GaN buffer layer 104 grown over a substrate 102 of sapphire, over which is grown 24 nanometer (nm) barrier layer 106 of unintentionally doped AlGaN (i-AlGaN) (e.g., i-Al_{0.25}Ga_{0.75}N). Advantageously, according to further aspects, various embodiments of the EBB AlGaN/GaN HEMTs can be fabricated on other substrates (e.g., SiC and Si, etc.).

As a further example, various embodiments of the disclosed EBB AlGaN/GaN HEMTs can be fabricated using commercially available Al_{0.25}Ga_{0.75}N/GaN HEMT wafers (e.g., from NTT-AT) such as those grown by MOCVD on a (0001) sapphire substrate. According to various aspects, a HEMT structure can comprise a low-temperature GaN nucleation layer over the substrate (not shown), with a 2 μm thick unintentionally doped GaN buffer layer 104 and a 24 nm undoped Al_{0.25}Ga_{0.75}N barrier layer 106, yielding a pinch-off voltage of −3.8 Volts (V), and sheet resistivity of the GaN buffer layer 104 can be larger than 10⁶ Ohms per square (Ω/□), with room temperature Hall measurements yielding a 2DEG density of 8.75×10¹² electrons per square centimeter (cm⁻²) and electron mobility of 1480 square centimeter per Volt second (cm²/Vs).

As described above, variations of the disclosed embodiments are intended to be encompassed within the scope of the subject matter described herein. For instance, the layer dimensions in the illustrative embodiment above serve to describe but one possible implementation. It can be appreciated that, in some instances, a buffer layer as thick as possible can be desirable. Advantageously, the disclosed embodiments avoid a practical limitation imposed on buffer layer thickness that can lead to buffer layer cracking as a result of built-in stresses. In addition, it should be noted that barrier layer thickness can typically vary from about 5 nm to about 30 nm or more.

While conventional AlGaN/GaN HEMTs can be further processed to produce the source 108, gate 110, and drain 112 structures, according to various embodiments of the disclosed subject matter, the disclosed AlGaN/GaN HEMTs can receive a fluorine ion implantation 206 treatment in addition to formation of the source 208, gate 210, and drain 212 structures.

As a non-limiting example, a device mesa can be formed by chlorine/helium (Cl₂/He) plasma dry etching in a Surface Technology Systems™ Inductively Coupled Plasma (ICP) system followed by source/drain ohmic contact formation with electron beam (e-beam) evaporated titanium (Ti), Al, Nickel (Ni) and gold (Au) annealed at 850 degrees Celsius (° C.) in nitrogen (N₂) ambient for 30 seconds. Ohmic contact resistance can typically be achieved at 0.8 Ohm millimeter (Ωmm). According to an aspect, gate electrodes can be formed 1 μm long for the EBB HEMT 204 and conventional HEMT 202 and fabricated separately, using Ni/Au e-beam evaporation and lift-off.

According to a further aspect, prior to gate 110/210 metal deposition, the gate 210 window of the EBB HEMTs 204 can be implanted by Fluorine-19 (¹⁹F⁺) ions. For example, as a non-limiting illustration of an embodiment in accordance with an aspect of the disclosed subject matter, Fluorine-19 ions can be implanted 206 in the heterostructure (102/104/106) imparted with a selected energy (e.g., 50 kilo electron Volts (keV)) and at a selected dose (e.g., 1×10¹² ion per square centimeter (cm⁻²)) using an ion implanter (e.g., a Varian CF3000) and Boron Trifluoride (BF₃) as the source to yield, by way of non-limiting example, an EBB AlGaN/GaN HEMT having a 2DEG density of 6.96×10¹² cm⁻² and an electron mobility of 920 cm²/Vs. According to yet another aspect of the disclosed subject matter, the HEMTs can be nitrogen ambient annealed at 400 degrees Celsius for 15 minutes.

As a measure of comparison, conventional AlGaN/GaN HEMTs can be fabricated according to standard processes, with EBB HEMTs fabricated on the same wafer. To that end, steps preparatory to HEMT fabrication can include processes to facilitate isolation between different devices for example, by mesa etching (e.g., by inductively coupled plasma reactive ion etching), ion implantation, etc. It can be appreciated that such device isolation can be performed in the event of integrating the disclosed devices and structures with other devices in fabrication of an integrated circuit. According to further aspects of an exemplary embodiment, the devices can be fabricated having gate length (L_{G}) of 1 μm, gate-to-source spacing (L_{GS}) of 1 μm, and gate-to-drain spacing (L_{GD}) of 2 μm.

It has been shown that a fluorine plasma treatment can be used to achieve enhancement-mode AlGaN/GaN HEMTs by incorporating negative fluorine ions in the AlGaN barrier 106 (not shown in 202). In addition, the plasma-deposited fluorine ions have been shown to effectively deplete the 2DEG in the channel and deliver a threshold voltage shift of a HEMT as large as +5 V. The fluorine plasma treatment can incorporate fluorine ions into the thin AlGaN layer to realize enhancement mode HEMTs, since the energy of fluorine ions in plasma is lower than that in an ion implanter. Advantageously, the fluorine plasma treated enhancement-mode AlGaN/GaN HEMT can incorporate an EBB to achieve enhancement-mode AlGaN/GaN HEMT with improved breakdown voltage.

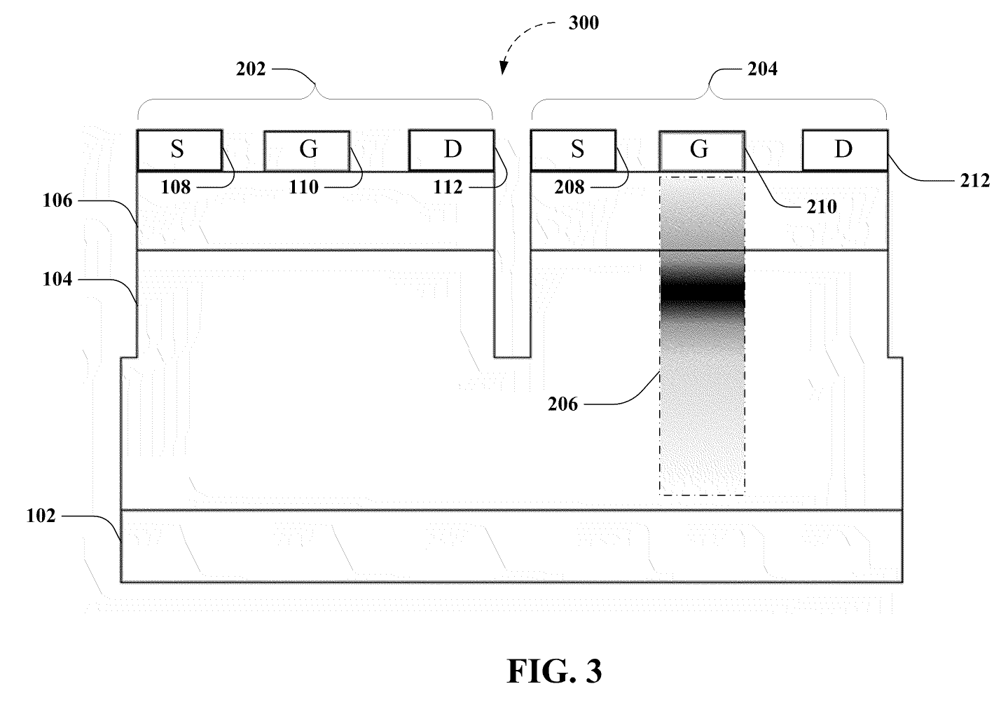

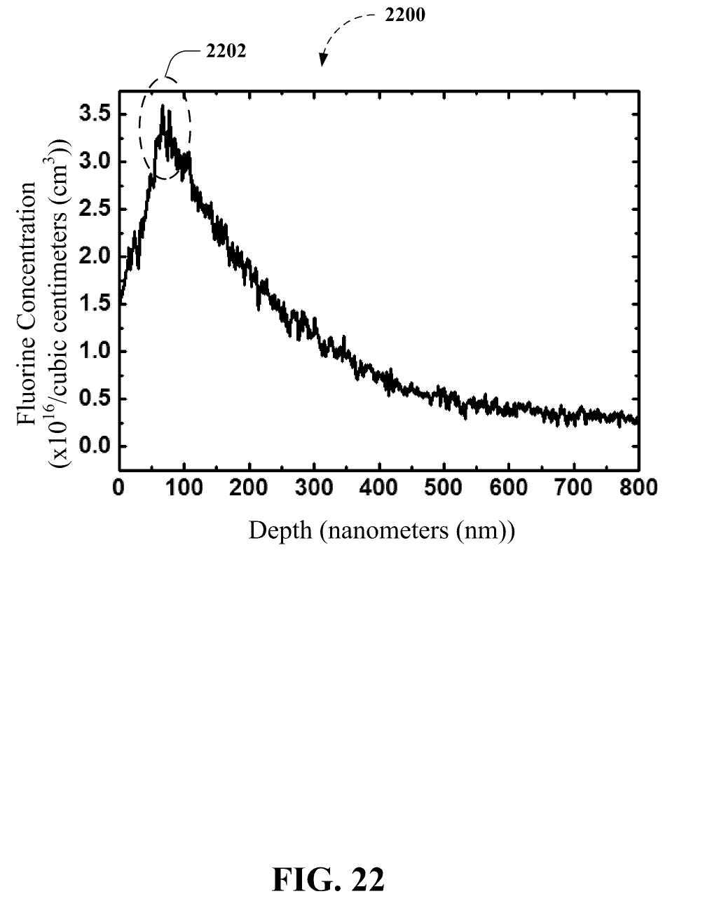

Accordingly, the disclosed subject matter provides an enhanced back barrier region or layer 206 that can effectively block source 208 injected electrons 114 from entering the high field region. Advantageously, this EBB region or layer 206 improves the three-terminal off-state breakdown voltage (BV_{off}) of the disclosed AlGaN/GaN HEMTs 204, as further described below, by implantation of negative fluorine ions at the back of the channel and raising the conduction band energy to provide an energy back barrier. It is also noted that, while the EBB region or layer 206 is depicted in FIG. 2 as a collection of discretely shaded regions to indicate relative differences in the fluorine concentration as the depth or position from the gate 210 changes, it can be appreciated that the actual concentrations can be a continuum of fluorine concentrations in the EBB region or layer 206, as shown as and described with reference to FIGS. 3 and 22, rather than as sub-regions of discrete concentrations.

For instance, FIG. 3 depicts an alternate schematic cross section 300 of a conventional AlGaN/GaN HEMT 202 and an EBB AlGaN/GaN HEMT 204 with fluorine ion implantation, according to an exemplary non-limiting embodiment of the disclosed subject matter. As described, the EBB layer or region 206 is more accurately depicted as a continuum or gradient of fluorine concentration in the EBB region or layer 206, rather than as sub-regions of discrete concentrations. Note that the enhanced back barrier region 206 of implanted fluorine is disposed within the buffer layer 106 and is spanning or extending across a portion of the heterojunction (e.g., the concentration of fluorine is non-zero in the buffer layer 104 side and the barrier layer 106 side of the heterojunction, with the peak fluorine concentration lying below the 2DEG channel).

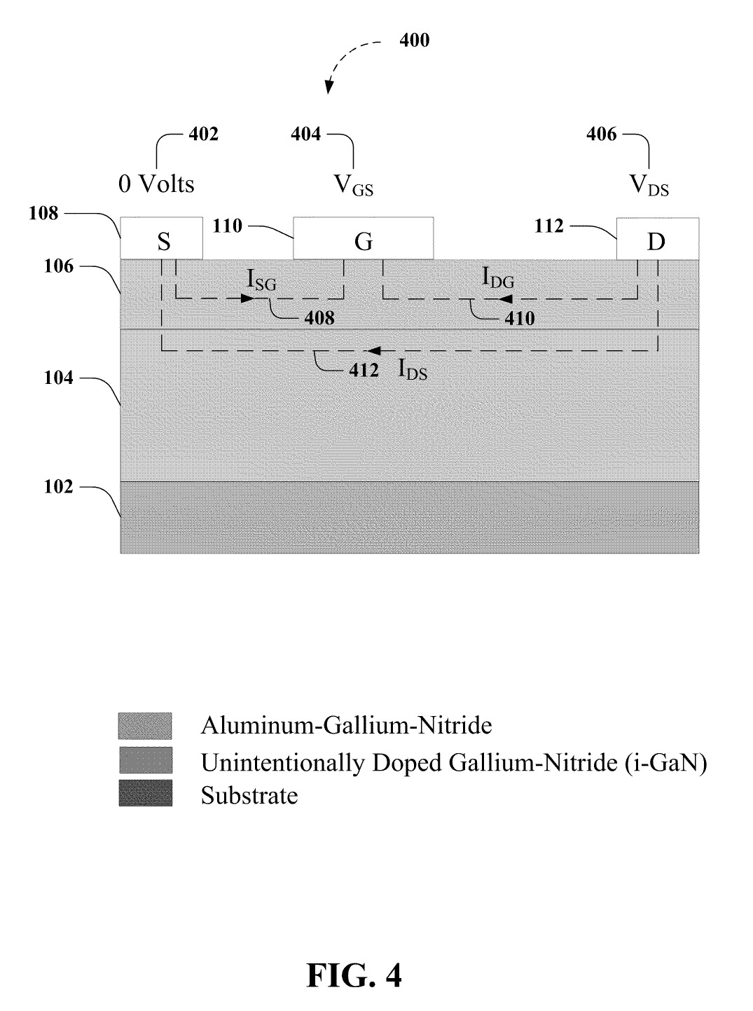

Three-terminal off-state (BV_{off}) can be defined as drain voltage at which the drain current density reaches 1 milliAmpere per millimeter (mA/mm) when the device is biased at off-state, using a conventional I-V test configuration shown in FIG. 4. FIG. 4 illustrates a test configuration for three terminal off-state breakdown of AlGaN/GaN HEMTs, in which V_{GS} (e.g., voltage relative to the device gate and source) 404 can be biased below pinch-off and V_{DS} (e.g., voltage relative to the device drain and source) 406 swept from 0 V to high voltage in order to yield a drain current of 1 mA/mm. Current values at the source 108/208, gate 110/210, and drain 112/212 terminals were recorded separately, as a function of V_{DS} at different gate bias.

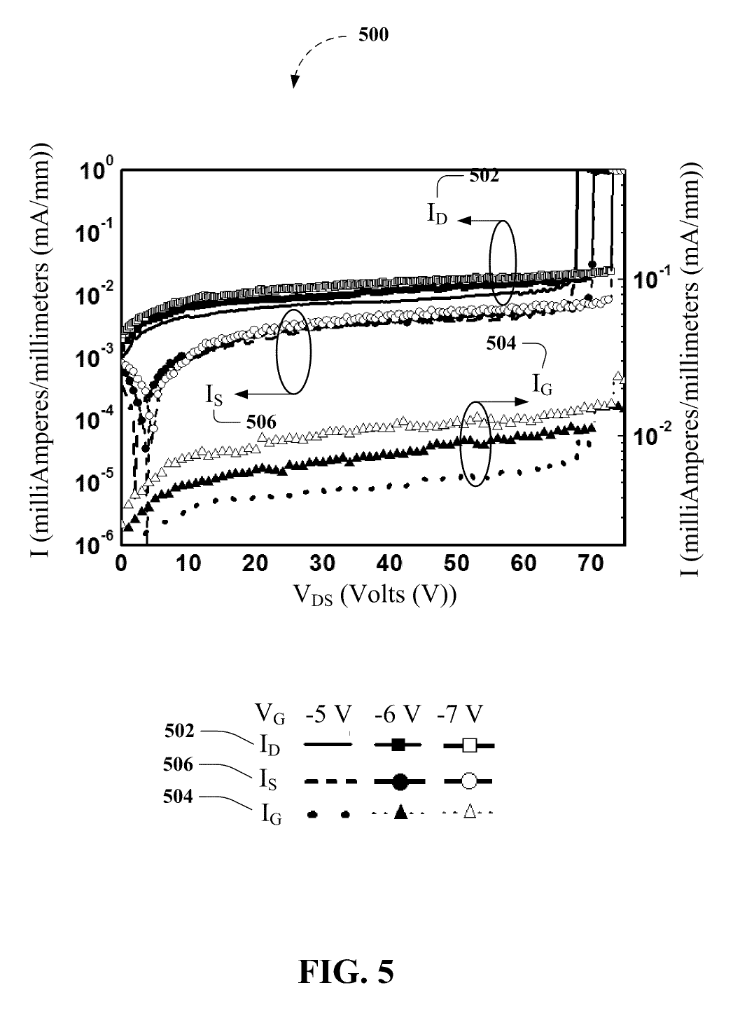

FIG. 5 depicts three terminal off-state breakdown characteristics 500 of an exemplary conventional HEMT 202 at different gate 110 biases. A sharp increase of the drain current 502 is observed when the drain voltage approaches a critical value, indicating a hard breakdown of the device 202. In addition, it is noted that the BV_{off} increases as the gate 110 bias becomes more negative, despite the higher gate leakage current 504, suggesting an alternative other than gate 110 injection (or leakage) as a dominant factor for device 110 breakdown.

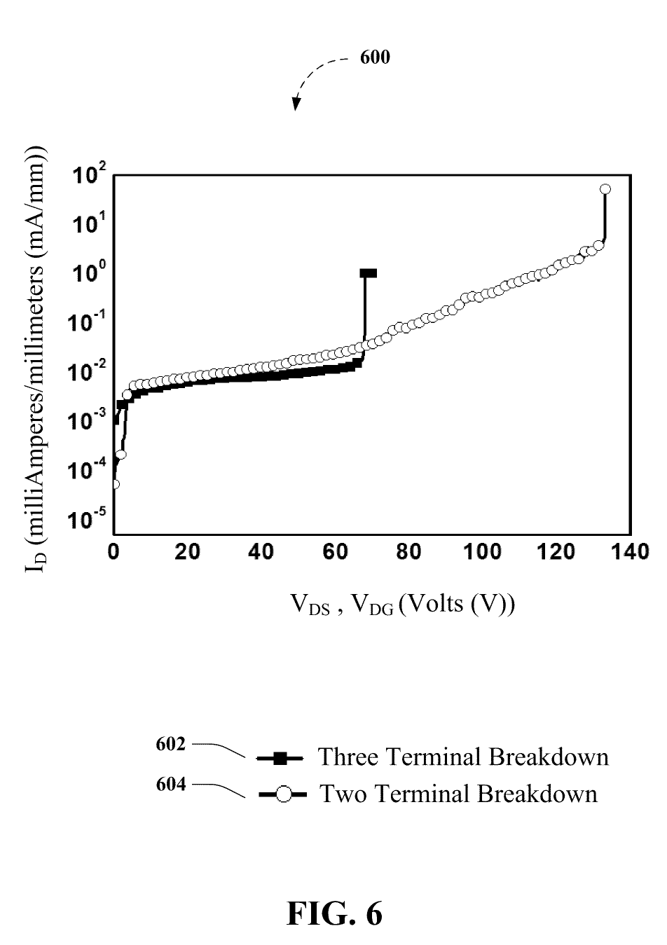

FIG. 6 depicts a comparison 600 of breakdown voltage at three-terminal 602 and two-terminal 604 test configurations, in which a much higher breakdown voltage is observed in the two-terminal configuration between the gate 110 and drain 112. It should be apparent that premature three-terminal breakdown is not induced by the gate injection as the high-quality gate barrier offers a low gate leakage current. In addition, it is noted that source current (I_{S}) (506 in FIG. 5) before the dip is negative, and its sign is reversed in the logarithmic plot. Thus, source current 506 is dominated by the source-gate leakage (I_{SG}) 408 when the drain 112 bias is low. Note further that I_{S} 506 changes to positive after the dip because the current component from the source to the drain (I_{DS}) 412 eventually exceeds the source-gate leakage current (I_{GS}) 408 as V_{DS} 406 increases.

In addition to typical I-V measurements, drain-current injection can be used to characterize the three-terminal off-state breakdown in order to differentiate the different breakdown processes. One advantage is the drain current limit that prevents the device under test from conducting excess current and burning out.

Accordingly, HEMT 202 can be biased with grounded source 108 and a fixed drain 112 current at 1 mA/mm, with V_{GS} 404 swept down from 0 V to −25 V and gate current (I_{G}) 504, V_{DS} 406, and V_{DG} (e.g., voltage relative to the device drain and gate) recorded as a function of V_{GS} 404. Note that during the sweep, the device is tuned from “on-state” to “off-state.”

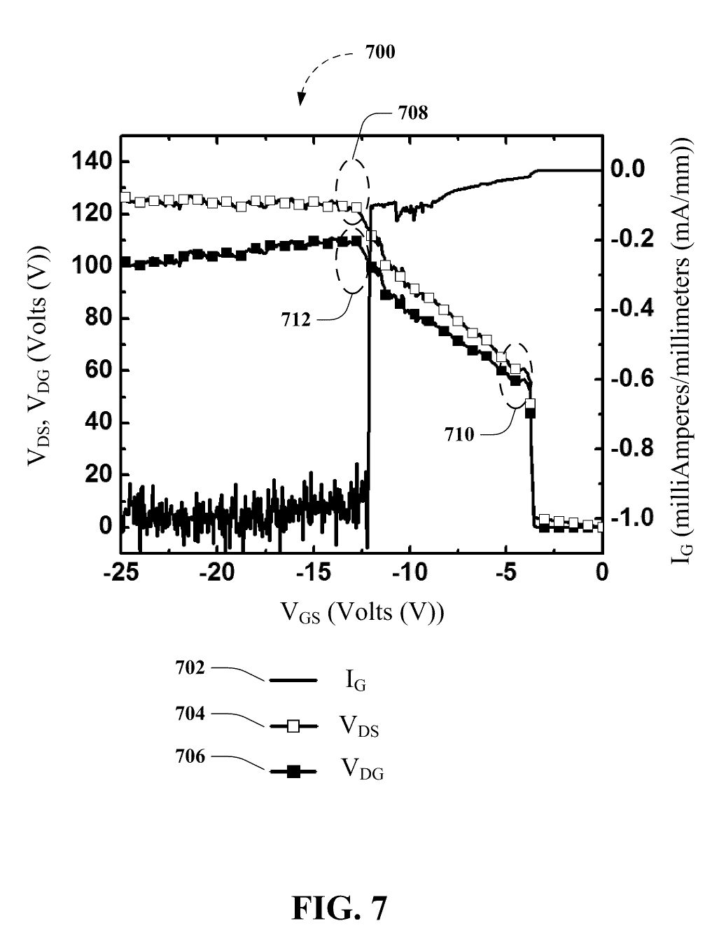

FIG. 7 depicts three terminal off-state breakdown characteristics 700 of a conventional AlGaN/GaN HEMT as measured by the above-described drain-current injection measurement method, where I_{G} 702 (device gate current), V_{DS} 704 (e.g., voltage relative to the device drain and source), and V_{DG} 706 (e.g., voltage relative to the device drain and gate) are depicted along with the BV_{DG} 708 (e.g., voltage relative to the device drain and gate for gate breakdown), BV_{DS} 710 (e.g., voltage relative to the device drain and source for channel breakdown), and the BV_{DS}^{G} 712 (e.g., voltage relative to the device drain and source for gate breakdown). Again, drain 108 current is fixed at 1 mA/mm and V_{GS} is swept from 0 V to −25 V.

As shown in FIG. 7, the breakdown at lower V_{DS} 704 is observed preceding the gate breakdown, where I_{G} 704 is still small in a conventional AlGaN/GaN HEMT. This suggests that the current path from the source 108 to the drain 112 should be in the GaN buffer layer 104. It can be appreciated that the as-grown GaN layer 104 is typically n-type even with growth optimization because of the background doping by impurities and intrinsic point defects, such as residual Si, Oxygen (O), and nitrogen vacancies, respectively. In addition, drain induced barrier lowering in the GaN buffer layer 104 worsens at larger depths from the 2DEG channel. As a result, electrons can be injected from the source to the high-field region through the buffer 104 initiating impact ionization in the channel at a large drain 112 bias. In this regard, current injected from the source 108 to the drain 112, resulting from unintentionally n-type background doping (e.g., due to intrinsic nitrogen vacancies or oxygen impurities, etc.) in the unintentionally doped GaN buffer layer (e.g., i-GaN layer) 104, can limit the breakdown voltage in practical HEMT devices.

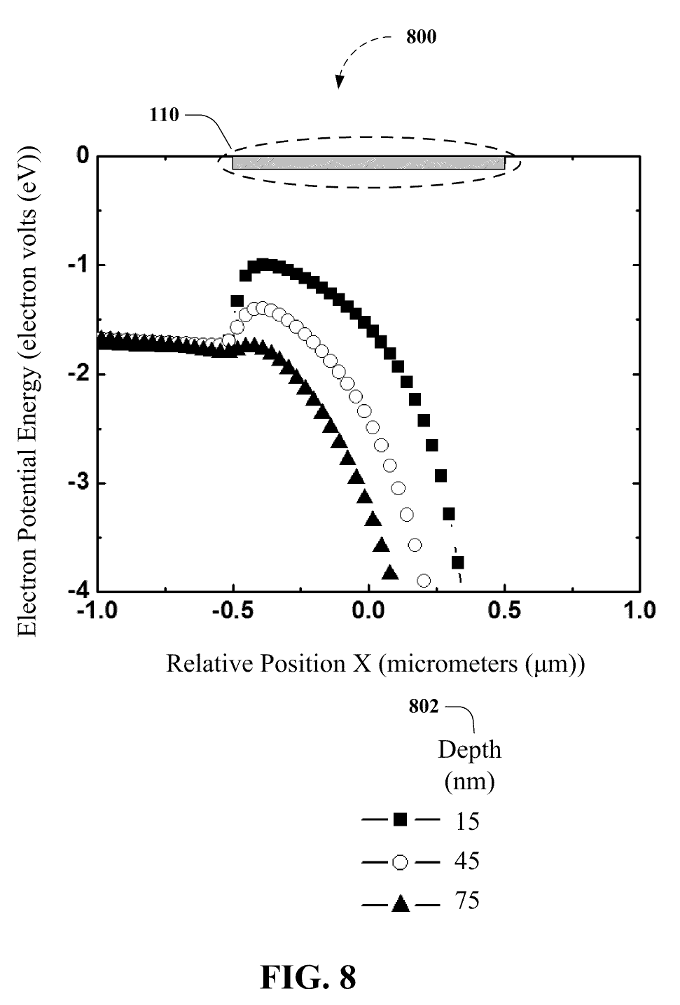

FIG. 8 depicts an exemplary non-limiting electron potential energy distribution 800 in the GaN buffer layer 104 as a function of relative position (X) and at different depths from the channel under an exemplary conventional AlGaN/GaN HEMT gate 110, in which the simulations were carried out using the Synopsys® Sentaurus tool and with V_{GS} and V_{DS} set at −5 V and 60 V, respectively. It is depicted in FIG. 8 that drain 112 induced barrier lowering in the GaN buffer layer 104 worsens at larger depths 802 from the 2DEG channel. The barrier between the source 108 and drain 112 almost disappears at a depth of 75 nm from the 2DEG channel, which indicates that the gate 110 has lost control in this region. Accordingly, electrons can be injected from the source 108 to the high field region in the channel following the electric field vector to initiate the impact ionization in the channel at large drain 112 bias.

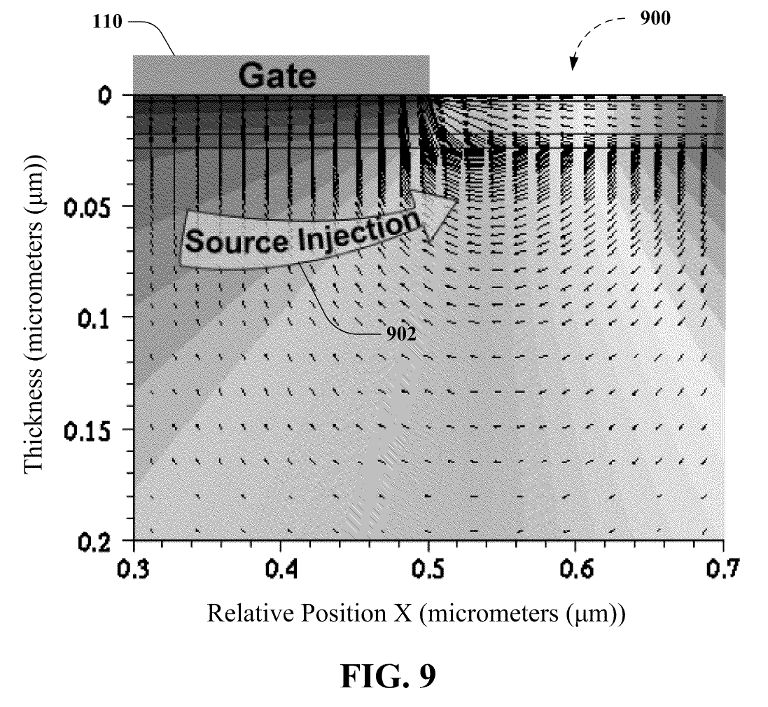

FIG. 9 depicts simulation 900 results of off-state potential energy distribution and electric field vectors under an exemplary non-limiting gate 110 region, according to various aspects of the disclosed subject matter, in which the simulation results are depicted using the Synopsys® Sentaurus tool with V_{GS} and V_{DS} are set at −5 V and 60 V, respectively. From FIG. 9, it can be seen that the source 108 (not shown) injected electrons 114 (902) can be swept to the high field region in the channel following the electric field vector to initiate the impact ionization in the channel at large drain 112 bias, as described above.

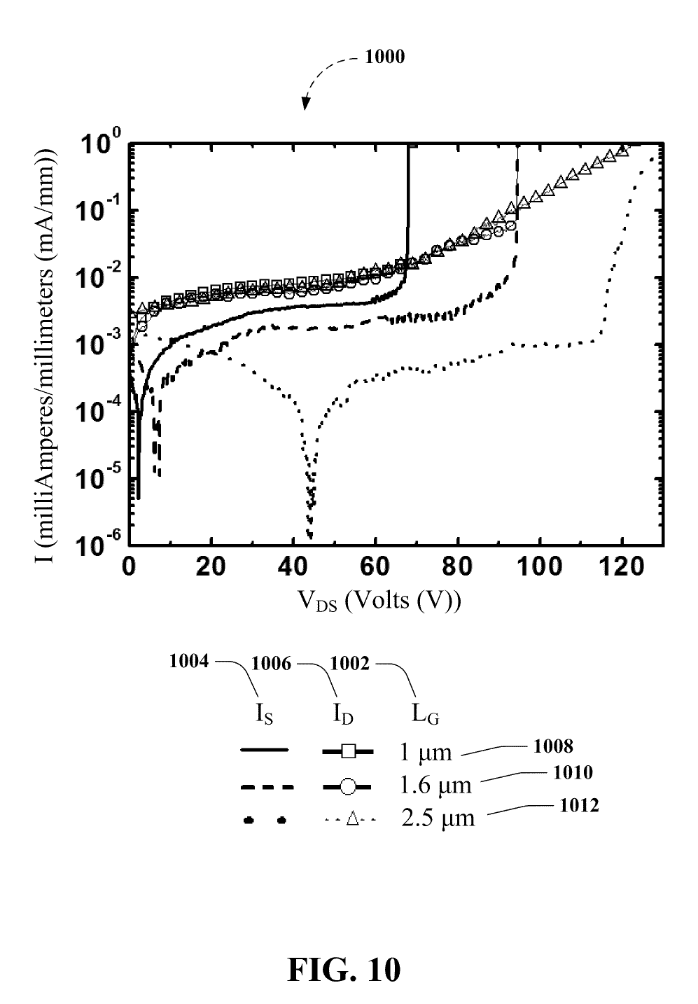

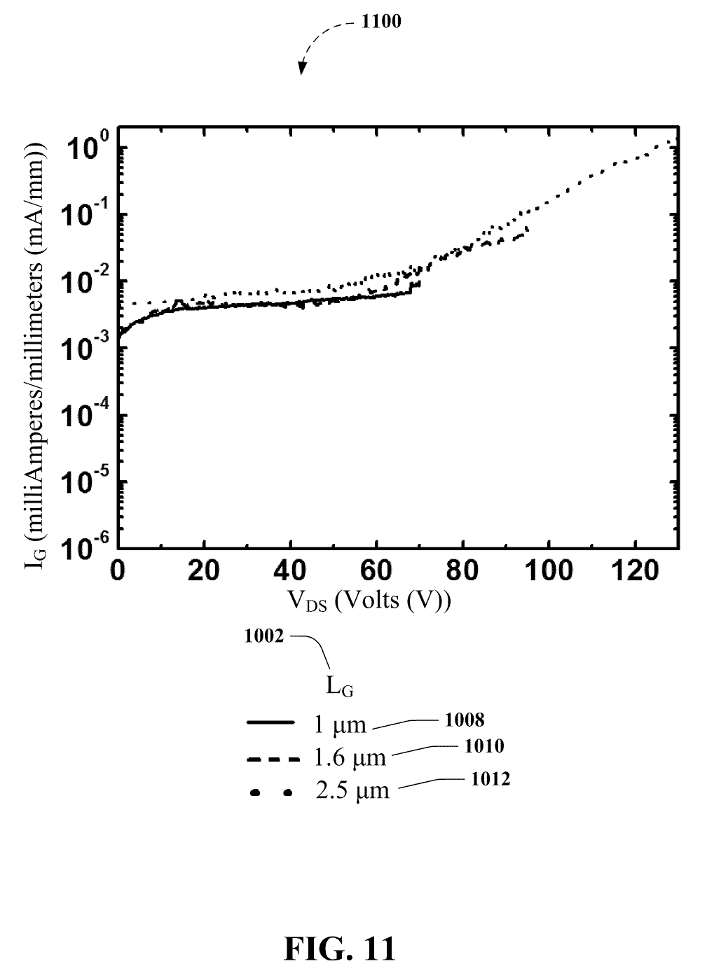

FIGS. 10-11 depict three terminal off-state breakdown characteristics 1000/1100 of an exemplary conventional AlGaN/GaN HEMT with different gate length (L_{G}) 1002, in which source current (I_{S}) 1004 and drain current (I_{D}) 1006 are depicted in FIG. 10 and the gate current (I_{G}) is depicted in FIG. 11. Off-state breakdown characteristics 1000/1100 of the HEMT device 202 with different gate lengths 1002 (1 μm 1008,1.6 μm 1010, 2.5 μm 1012) can be measured to verify that the source 108 injected electrons 114 (902) are a substantial factor in premature device breakdown, as it is known that the DIBL effect weakens with the increase of the gate length 1006. Accordingly, it can be appreciated that the current injected from the source 108 to the high field region should be smaller in devices with large gate 110 length 1002 and a higher breakdown voltage should be achieved. It is clear in FIG. 10 that the BV_{off} is larger in devices with larger gate 110 length 1002 due to the smaller source injection current 1004, despite the fact that the gate current (I_{G}) is larger, as depicted in FIG. 11.

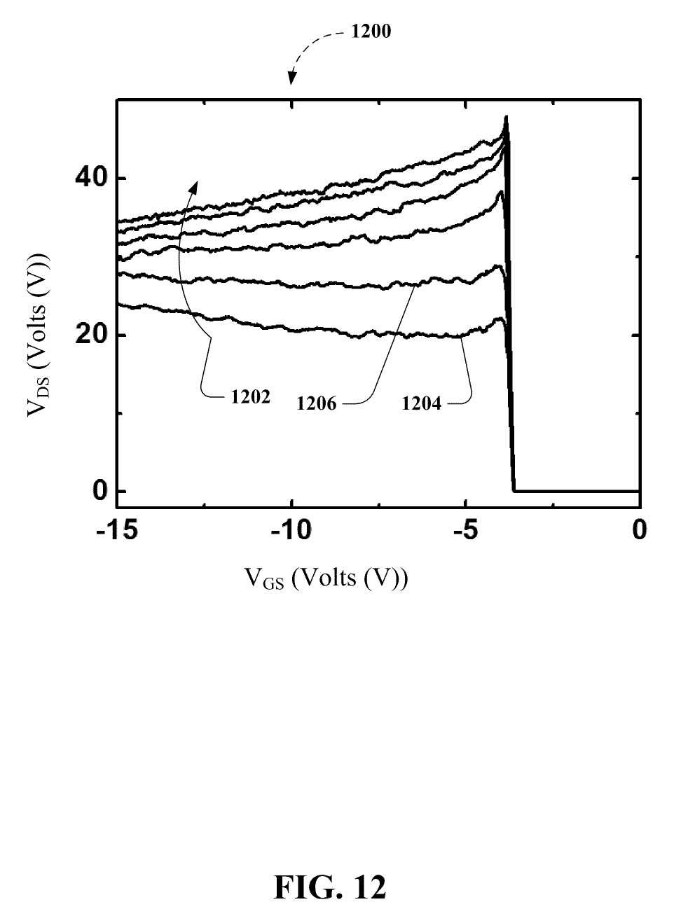

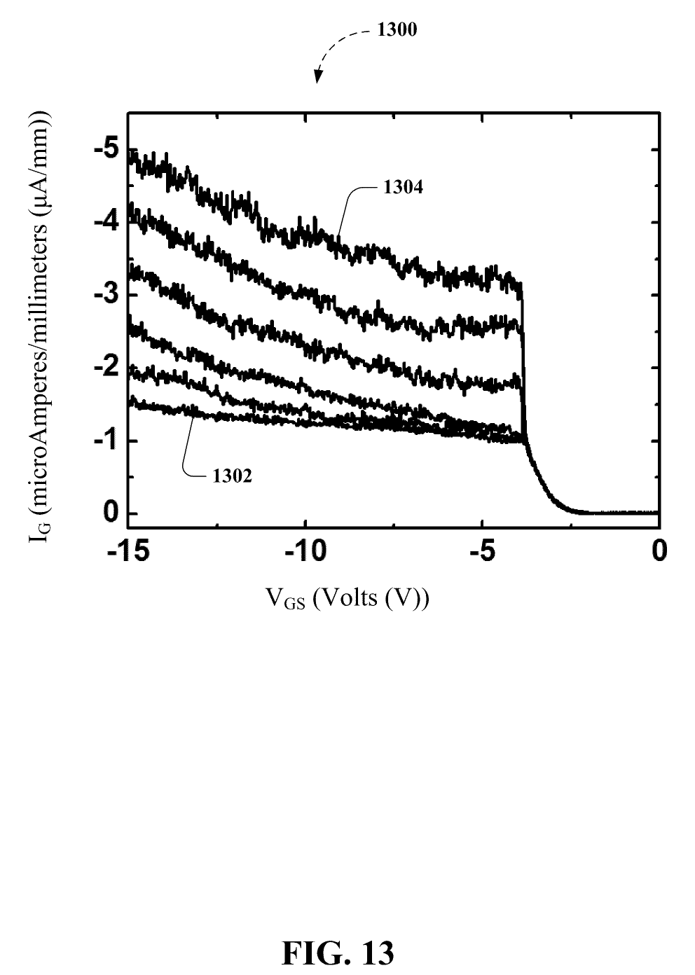

Exemplary embodiments of the HEMTs 202 can be tested with lower drain injection currents in order to obtain an insight into device operation at off-state. FIGS. 12-13 depict three terminal off-state breakdown characteristics 1200/1300 of an exemplary conventional AlGaN/GaN HEMT 202 using drain-current injection with small drain injection currents from 5 (1302) to 10 (1304) microAmperes per millimeters (μA/mm) and step 1202 of 1 μA/mm, in which drain-source voltage and gate current as a function as V_{GS} are depicted in FIGS. 12 and 13, respectively. FIG. 12 indicates that no channel breakdown is observed in such drain current levels. Thus, the drain-source or drain-gate leakage currents induced by thermal and thermal-field emission can sustain the drain current when the injected drain current is relatively low. Note that the drain-source voltage increases when V_{GS} sweeps from −7 V to −15 V at injection current level of 5 μA/mm (1204) and 6 μA/mm (1206), which is opposite to other current levels.

FIG. 13 indicates that source current dominants drain current when the injection current is smaller. Thus, source current is reduced as V_{GS} is swept from −7 V to −15 V. This indicates that higher drain voltage is needed to keep the constant drain injection current. Consequently, the gate leakage current increases its contribution to the maintenance of the drain injection current as it is increased. It can be appreciated that constant gate-drain voltage should be achieved to keep constant drain current. Accordingly, drain-source voltage decreases when V_{GS} sweeps from pinch-off voltage to large negative values.

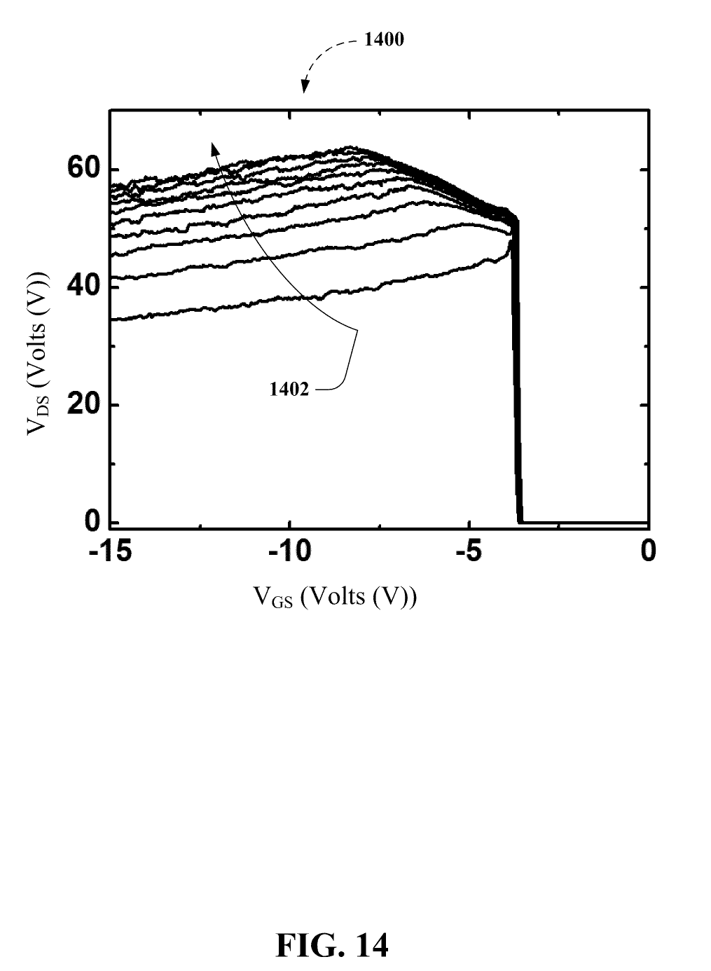

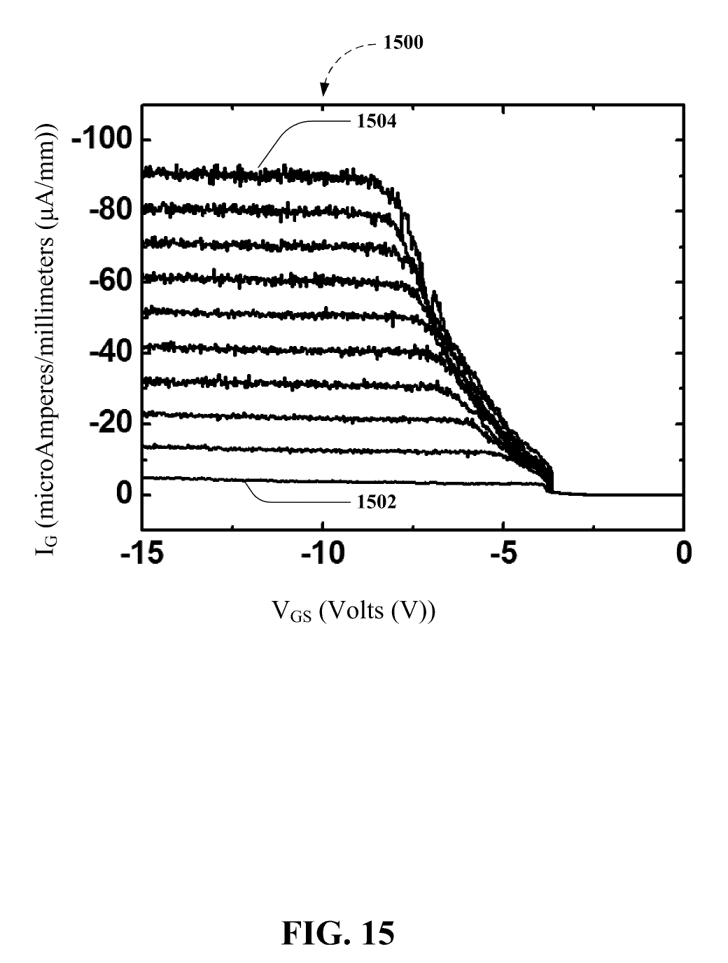

FIGS. 14-15 depict three terminal off-state breakdown characteristics 1400/1500 of an exemplary conventional AlGaN/GaN HEMT using drain-current injection with large drain injection currents from 10 μA/mm (1502) to 100 μA/mm (1504) and step 1402 of 10 μA/mm, in which drain-source voltage and gate current as a function as V_{GS} are depicted in FIGS. 14 and 15, respectively. It can be seen that the source-induced and gate-induced breakdowns are both observed when the drain injection current is higher than about 20 μA/mm. It can be appreciated that impact ionization most likely occurs at such current levels since leakage currents induced by thermal and thermal-field emission typically cannot sustain such high current levels. As shown in FIG. 15, source current dominates drain current in the channel breakdown region, while gate current dominates in the gate breakdown region, which is different from that with small injection current levels depicted in FIGS. 12-13.

As mentioned above, source injected current decreases when the gate bias is more negative, thus, higher drain-source voltage is needed to sustain constant drain current in the source-injection induced breakdown region as shown in FIG. 15. In the gate-induced breakdown region, gate current is a major part of the drain current. These observations indicate competition between the source leakage current and gate leakage current when the injected drain current is relatively low. It should be noted that the dominant leakage path is determined by the bias condition and, more importantly, by the basic properties of the device, such as, but not limited to, the buffer 104, Schottky gate 110 quality, and the device dimensions.

These observations also indicate that there is competition between pure leakage current and leakage current induced impact ionization when the injected drain current is high. As can be appreciated, impact ionization would likely not happen if leakage current can be as high as the injected drain current level. Otherwise, impact ionization is the dominant breakdown mechanism. Additionally, in the framework of impact ionization, there is also exit competition between the source injection and gate injection, as previously described.

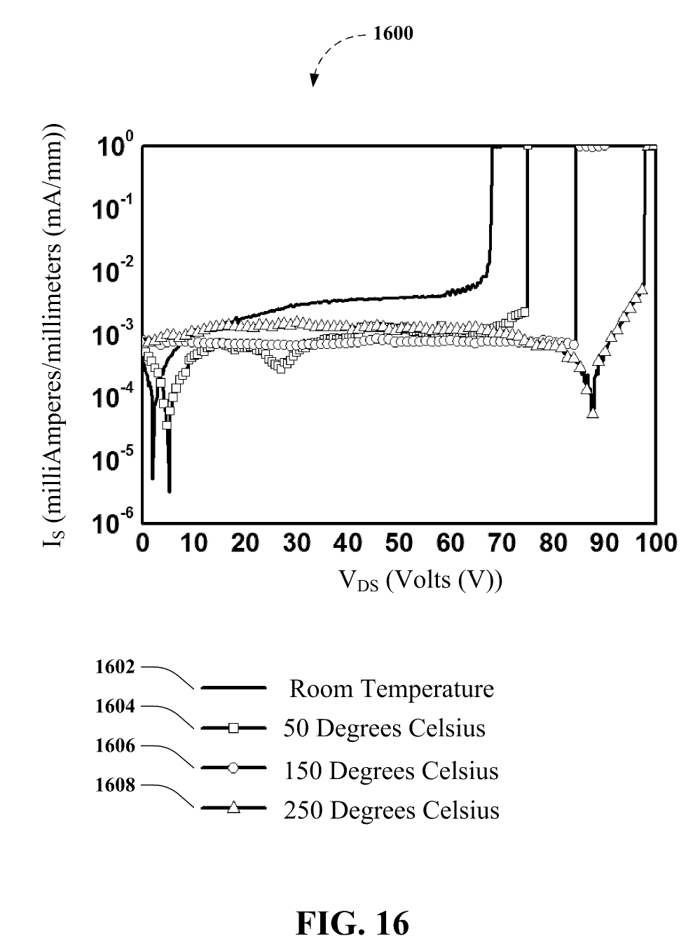

FIG. 16 depicts three terminal off-state breakdown characteristics 1600 of an exemplary fabricated HEMT 202 at various temperatures, in which source currents are depicted at room temperature 1602, 50° C. (1604), 150° C. (1606), and 250° C. (1608). In FIG. 16, gate length is 1 μm, and the gate bias is set to be −5 V, where only source currents are depicted for clarity. It can be seen that breakdown voltage increases when the temperature is raised. Note that the dip in source current shifts to higher V_{DS} as the temperature is increased, which is caused by the increase of source-gate leakage at higher temperature when a higher V_{DS} is needed to achieve larger I_{DS} in order to reverse the direction of the source current.

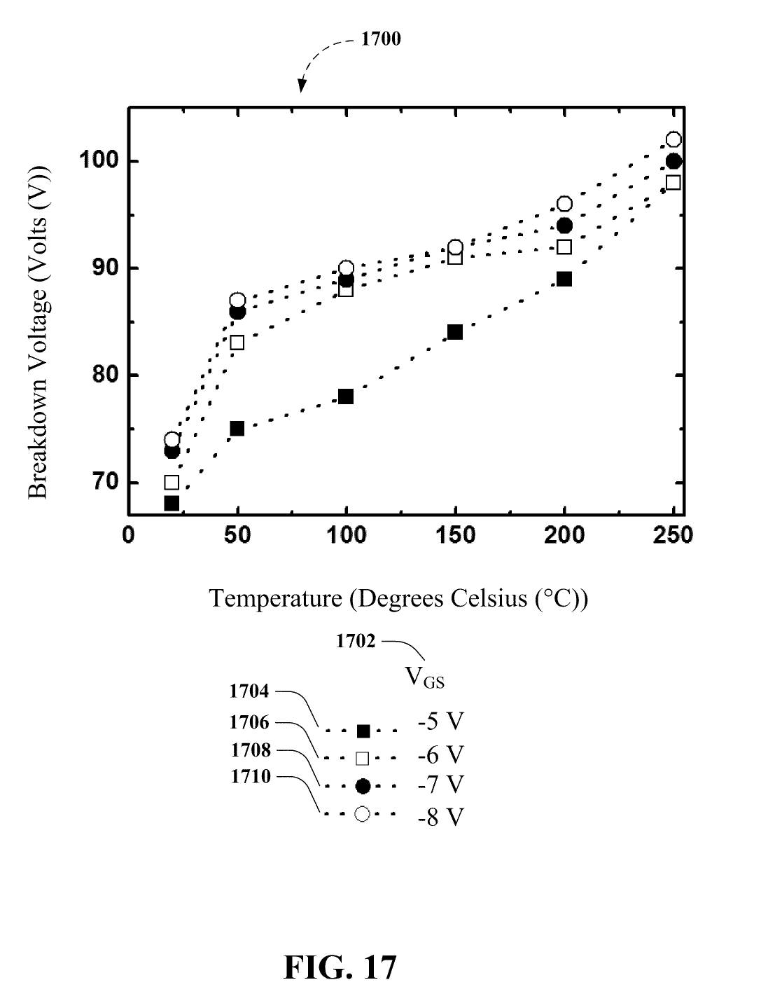

FIG. 17 depicts temperature dependence 1700 of three terminal off-state breakdown voltage for an exemplary conventional AlGaN/GaN HEMT 202 according to various aspects of the disclosed subject matter. FIG. 17 shows the temperature dependence of off-state breakdown voltage of the 1 μm gate length device at different negative gate bias 1702 (−5 V (1704), −6 V (1706), −7 V (1708), −8 V (1710)). A positive temperature coefficient is observed in all bias conditions, which is a typical signature of impact ionization.

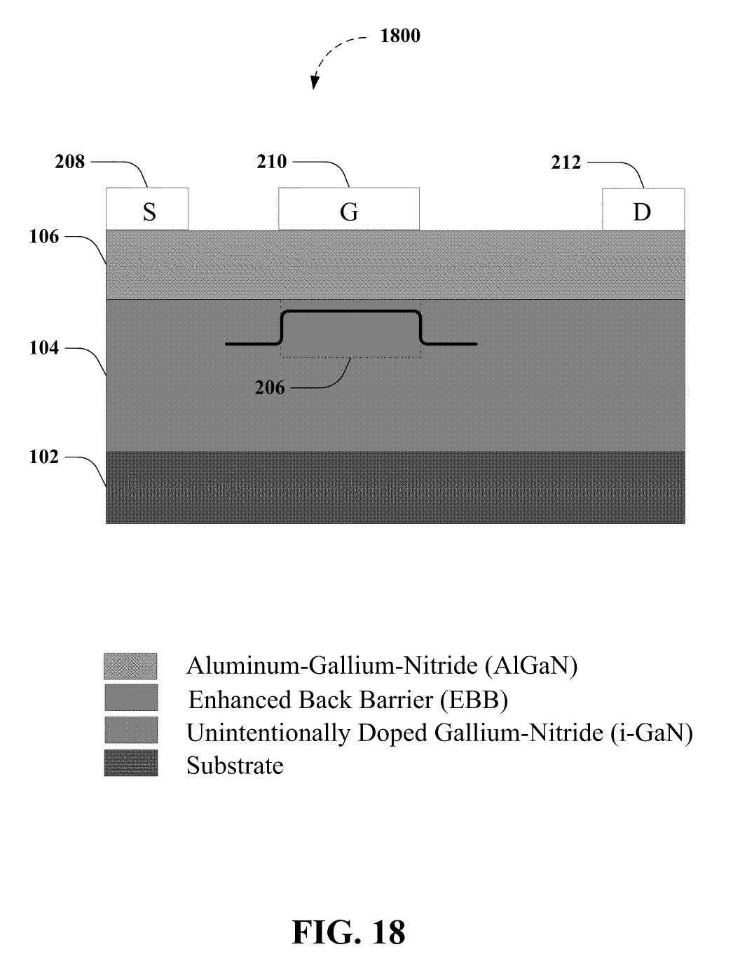

FIG. 18 illustrates a schematic cross section of an exemplary non-limiting embodiment 1800 of an enhanced back barrier AlGaN/GaN HEMT, or EBB AlGaN/GaN HEMT, in which implanted fluorine ions 206 in the GaN buffer 104 under the channel and in the gate region form a back barrier 206 reducing source-injection. According to various aspects of the disclosed subject matter, the HEMT structure can be fabricated on a commercial AlGaN/GaN wafer and can comprise a low-temperature GaN nucleation layer (not shown), a 2 μm thick unintentionally doped GaN buffer layer 104 and a 24 nm undoped Al_{0.25}Ga_{0.75}N barrier layer 106, with typical sheet resistivity of the GaN buffer layer 104 larger than 10⁶ Ω/□, and where room temperature Hall measurements typically yield a 2DEG density of 8.75×10¹² cm⁻² and an electron mobility of 1480 cm²/Vs. EBB HEMTs 204 can be fabricated by implanting ¹⁹F⁺ ions under the gate 210 region with a selected energy of 50 keV and at selected dose of 1×10¹² cm⁻² using a Varian CF3000 ion implanter. As depicted in FIGS. 2-3 conventional AlGaN/GaN HEMTs 202 can also fabricated on the same wafer, e.g., for comparison purposes or otherwise, according to standard processes.

According to further aspects, the devices (202/204) can be fabricated with a gate length L_{G} of 1 μm, a gate-source spacing L_{GS} of 1 μm, and a gate-drain spacing L_{GD} of 2 μm. In addition, the devices can be annealed at 400° C. for 15 minutes in N₂ ambient. According to an aspect of the particular embodiment, EBB HEMT 204 typically results in a 2DEG density of 6.96×10¹² cm⁻² and an electron mobility of 920 cm²/Vs in the implanted region.

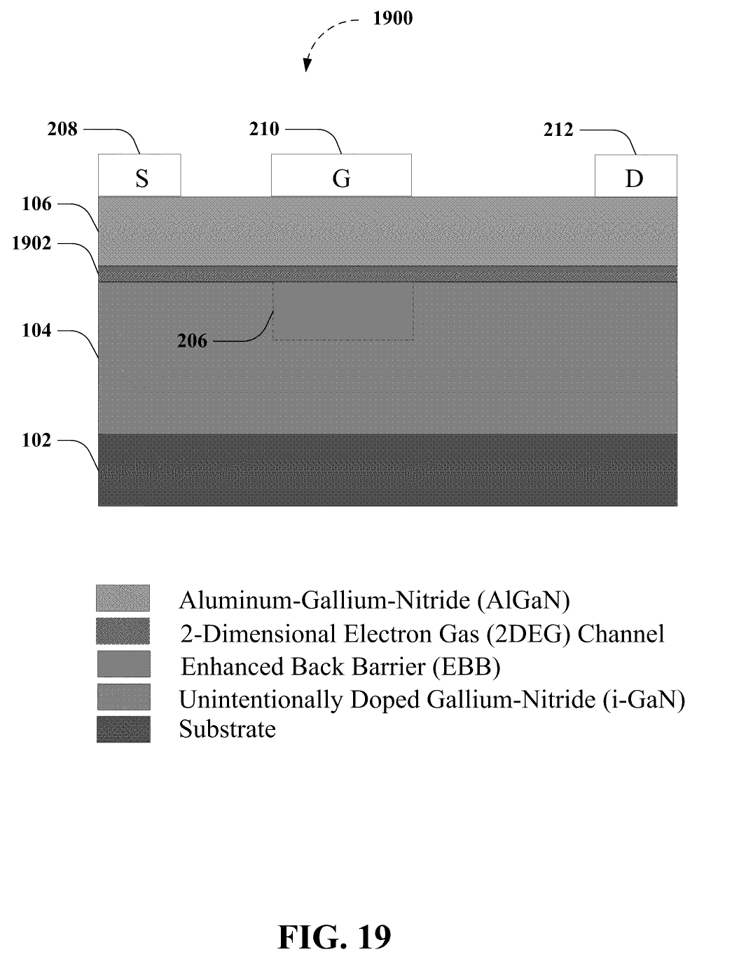

FIG. 19 further illustrates a schematic cross section of an exemplary non-limiting embodiment 1900 of an enhanced back barrier AlGaN/GaN HEMT 204, according to various aspects of the disclosed subject matter. Exemplary embodiment 1900, as described with reference to FIGS. 2-3 and 18, depicts a 2-Dimensional Electron Gas (2DEG) channel 1902 at the heterojunction or interface of the AlGaN barrier layer 106 and the i-GaN buffer layer 104.

It is also noted that while the 2DEG channel 1902 is depicted as a discrete region adjacent to and between the AlGaN barrier layer 106 and the i-GaN buffer layer 104, 2DEG Channel 1902 is comprised of a narrower-bandgap channel at the heterojunction created due to the different band-gap materials forming an electron potential well in the conduction band on the non-doped side of the heterojunction. It is further highlighted that, similar to the discussion regarding fluorine concentration in reference to FIGS. 2, 3, and 22, although the EBB region or layer 206 is depicted as a discretely and homogenously shaded region to indicate the presence of the implanted fluorine concentration, the actual concentration profile, according to various embodiments, can be a continuum or gradient of fluorine concentrations in the EBB region or layer 206, as shown as and described, for example, with reference to FIGS. 3 and 22.

As discussed above, source injection could be mitigated with low-leakage buffer by compensating doping with C or Fe. However, such compensating doping usually creates deep-level acceptors in the buffer 104, which may cause device instability, especially at high drain voltage. Using AlGaN buffer 104 (not shown) has proven to be challenging, as there are still great difficulties in the growth of thick AlGaN buffer layer with Al content higher than 5 percent (%). In addition, transport properties of the 2DEG in such structures is relatively poor comparing with that of conventional AlGaN/GaN heterostructures. Growing an epitaxial back barrier incorporating an Indium Gallium Nitride (InGaN) notch layer at the back of the channel to utilize the InGaN layer's piezoelectric polarization to raise the local energy has been performed with associated enhanced back barrier confinement. However, it has not been proven whether the InGaN layer, which is only a few nanometers away from the heterojunction interface and features narrower bandgap, delivers any improvement in such HEMTs' off-state breakdown.

As previously described, an enhanced back barrier that blocks the source injected electrons 114/902 from entering the high field region can improve the three-terminal BV_{off}. In addition, fluorine plasma treatment can be employed to fabricate enhancement-mode AlGaN/GaN HEMTs by incorporating negatively charged fluorine ions in the AlGaN barrier 106.

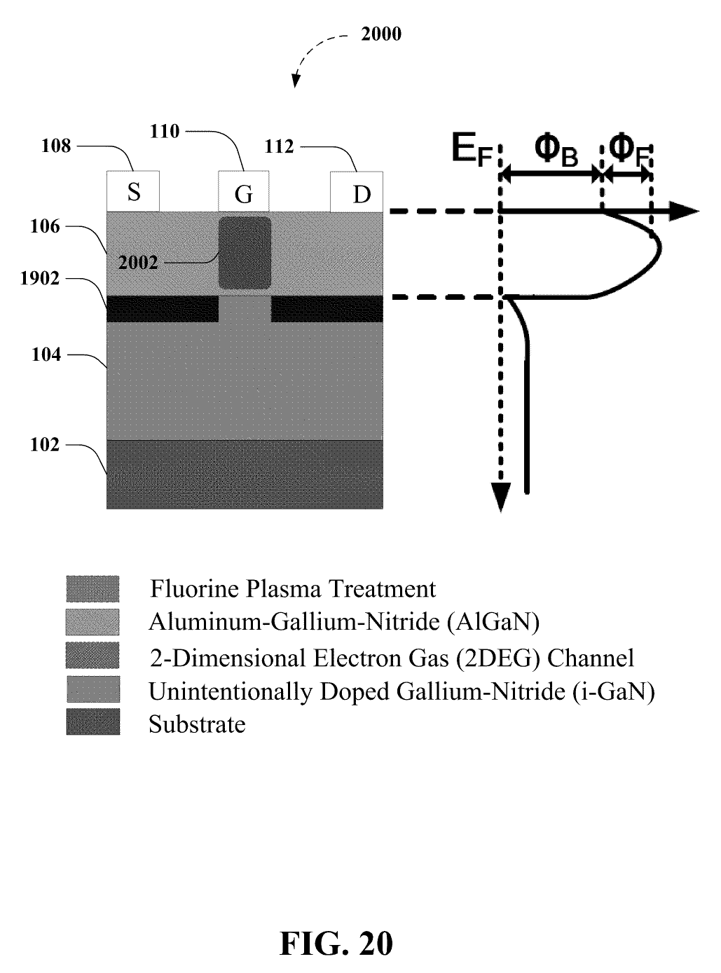

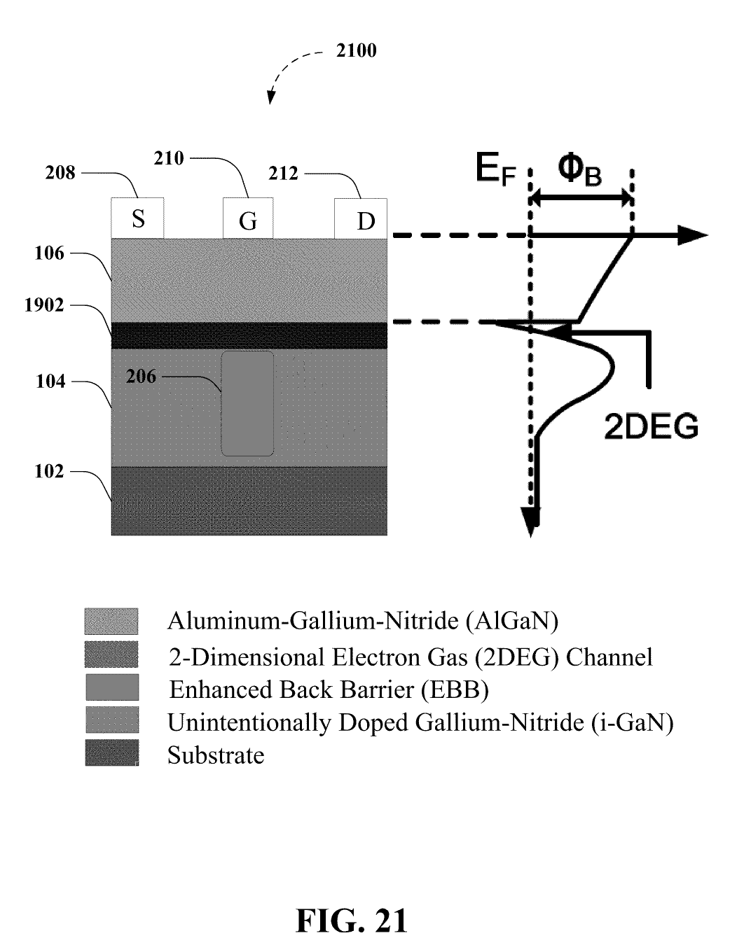

For example, FIGS. 20-21 illustrates particular aspects of an exemplary enhancement mode AlGaN/GaN HEMT 2000 fabricated by fluorine plasma treatment 2002 and an exemplary embodiment 2100 of an enhanced back barrier HEMT using fluorine ion implantation 206, respectively, in which the Fermi level (E_{F}), energy diagrams, and associated work functions are illustrated. In FIG. 20, it is shown that the fluorine ions can effectively deplete the 2DEG channel 1902 and deliver a threshold voltage shift of the HEMT as large as +5 V as illustrated qualitatively on the right panel of FIG. 20. In this enhancement mode AlGaN/GaN HEMT 2000, fluorine ions can be located in the AlGaN barrier layer 106 as previously described.

As discussed above, fluorine ions can be implanted 206 to the back side of the 2DEG channel 1902, creating an energy back barrier that can block the source-injection as illustrated qualitatively in the right of FIG. 21. It should be noted that the charge state of fluorine ions used in conventional ion implantation are positive before being implanted into the heterostructure, but are assumed to be negative once implanted due the strong electronegativity of fluorine.

For example, fluorine ions implanted at an energy of 10 keV and at a dose of 1.5×10¹³ cm⁻² near the channel of AlGaN/GaN heterostructures 204 can reveal the charge state of fluorine after implantation. For instance, a shift of 3 V in the threshold voltage can be observed, indicating that the charge state of fluorine ions has changed to negative when they are incorporated in III-nitride materials because of the strong electronegativity of the fluorine atoms.

As briefly described above, FIG. 22 depicts an exemplary Secondary Ion Mass Spectroscopy (SIMS) profile 2200 of implanted fluorine ions in an exemplary non-limiting embodiment of an EBB layer or region 206. According to an aspect, the energy of fluorine ions during implantation can be chosen to be 50 keV at a dose of 1×10¹² cm⁻², to develop a fluorine concentration profile with a peak fluorine concentration under the 2DEG channel 1902. According to an aspect, an implant energy can be chosen by Transport-of-Ions-in-Matter (TRIM) simulation, or other suitable calculation, in order to derive parameters for the implantation of the fluorine ions to the back of the 2DEG channel. It should be noted that the SIMS profile of FIG. 22 was obtained by increasing the dose to 1×10¹⁴ cm⁻² to capture a reliable SIMS signal.

Note that in the exemplary embodiment of the EBB AlGaN/GaN HEMT 204 with fluorine ion implantation, the peak fluorine concentration 2202 is approximately 66 nm from the surface of the AlGaN barrier layer 106 and approximately 42 nm from the heterostructure interface formed between i-AlGaN barrier layer 106 and the i-GaN buffer layer 104 (e.g., under the 2DEG channel), consistent with the results from TRIM simulation. Thus, in this exemplary non-limiting illustration, the implanted fluorine of the EBB layer or region 206 can be said to comprise a peak fluorine concentration located in the buffer layer 104 adjacent to the interface (e.g., under the 2DEG channel).

As depicted in FIGS. 2-3, 18-19, and 21, the disclosed subject matter provides AlGaN/GaN HEMTs 204 implanted with Fluorine-19 ions under the gate 210 region. For example, as described above, Fluorine-19 ions can be implanted in the heterostructure (102/104/106) imparted with a selected energy (e.g., 50 kilo electron Volts (keV)) and at a selected dose (e.g., 1×10¹² ion per square centimeter (cm⁻²)) using an ion implanter (e.g., a Varian CF3000).

It can be appreciated by one having ordinary skill in the art that the ion energy and dose, as well as location, as further described below, of the EBB region or layer 206 can be adjusted for different requirements of the fluorine distribution profiles and the amount of energy band increase. Accordingly, such embodiments should not be limited by any of the other exemplary non-limiting embodiments as described herein. Rather the claims appended hereto should be afforded the full breadth and scope of the claimed subject matter as disclosed and described herein.

It is also noted that the negatively charged fluorine ions raise the back barrier in the GaN buffer 104. For example, according to an aspect of the disclosed subject matter, by implanting ¹⁹F⁺ ions with an energy of 10 keV at a dose of 1.5×10¹³ cm⁻² near the channel of AlGaN/GaN heterostructures a shift of threshold voltage about +3 V can be observed, indicating that the charge state of fluorine ions has changed to negative after implantation because of the strong electronegativity of fluorine atoms.

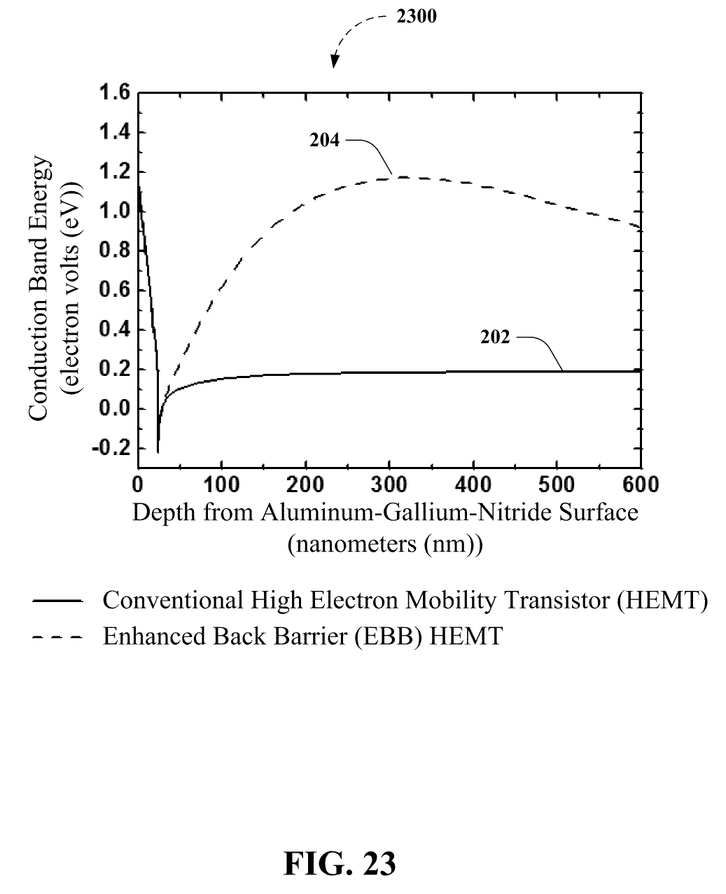

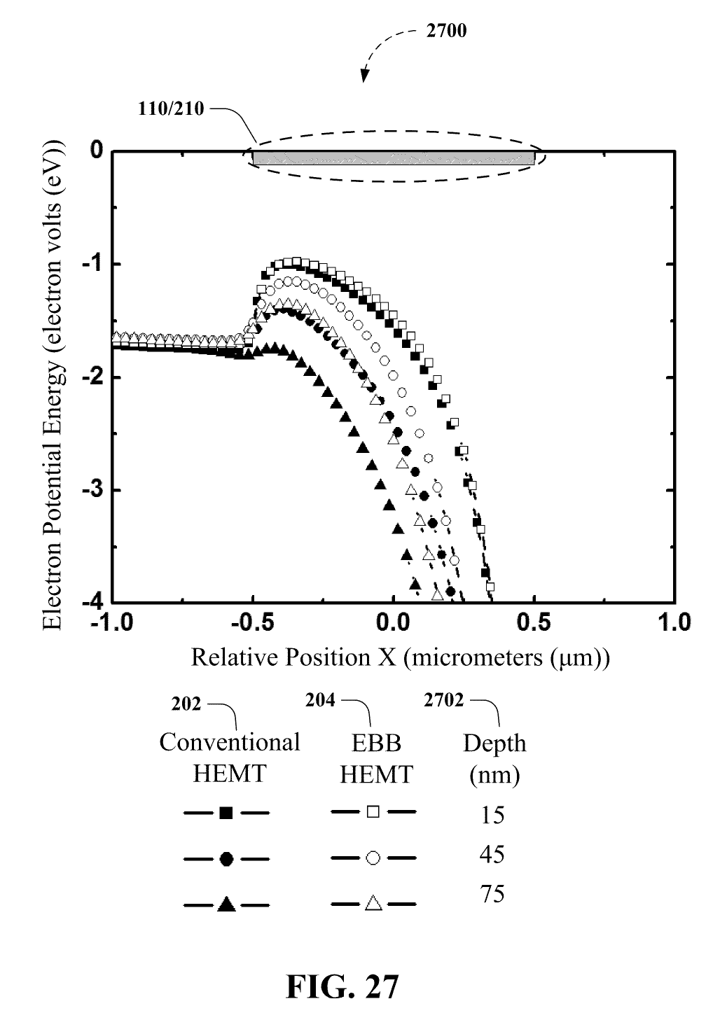

For example, FIG. 23 depicts a simulated zero bias conduction band profile 2300 of exemplary non-limiting AlGaN/GaN heterostructures before (e.g., conventional AlGaN/GaN HEMT heterostructure) 202 and after (EBB AlGaN/GaN HEMT) 204 fluorine ion implantation, according to various aspects of the disclosed subject matter. For the purposes of simulation, the effective n-type background doping in the buffer is assumed to be 2×10¹⁵ cm⁻³. Note that the conduction band of the GaN buffer layer 104 increased about 1 eV with the fluorine ions' modulation raising the energy barrier in the buffer layer 104 under the gate 210 region in the HEMTs 204. Thus, the band modulation by negatively charged fluorine ions can be expected to increase the barrier in the GaN layer 104 under the 2DEG channel as described below regarding FIG. 27.

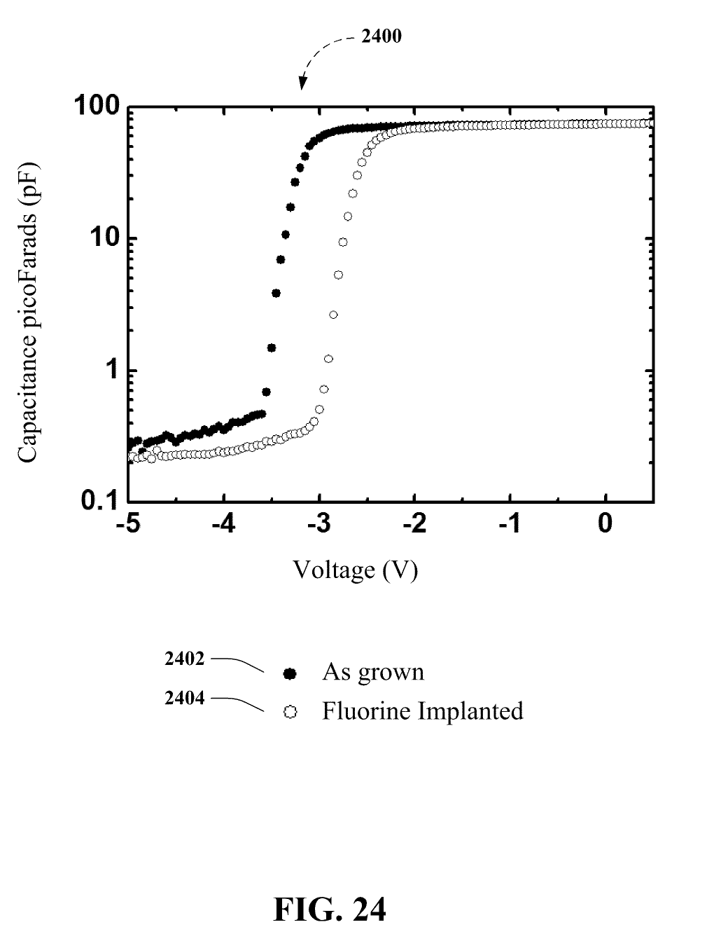

FIG. 24 depicts capacitance-voltage curves 2400 of exemplary non-limiting AlGaN/GaN heterostructures 202 before (e.g., as grown 2402) and after 204 fluorine ion implantation 2404, with maximum to minimum capacitance ratio (Cₘₐₓ/Cₘᵢₙ) increasing from 265 to 325, respectively. The enhanced back barrier leads to better buffer 104 isolation, which is reflected in the C-V characteristics 2400. According to an aspect, sheet resistance of heterostructure 204 was measured to be 1073 Ω/□ after implantation using the on wafer Transmission Line Method (TLM) pattern, which is about two times of the original value 484 Ω/□ in the as-grown sample 202. This indicates potential mobility degradation as a result of impurity incorporation and crystal damages. It can be appreciated that the sheet resistance degradation can occur in the implanted region 206 without affecting resistance in the source 208 and drain 212 access regions. In further aspects of various embodiments, on-wafer room temperature Hall measurements on the implanted area yield a 2DEG density of 6.17×10¹² cm⁻² and an electron mobility of 947 cm²/Vs. A shift of threshold voltage from −3.8 V to −3.0 V is a result of the energy band modulation in the channel region by the negative fluorine ions.

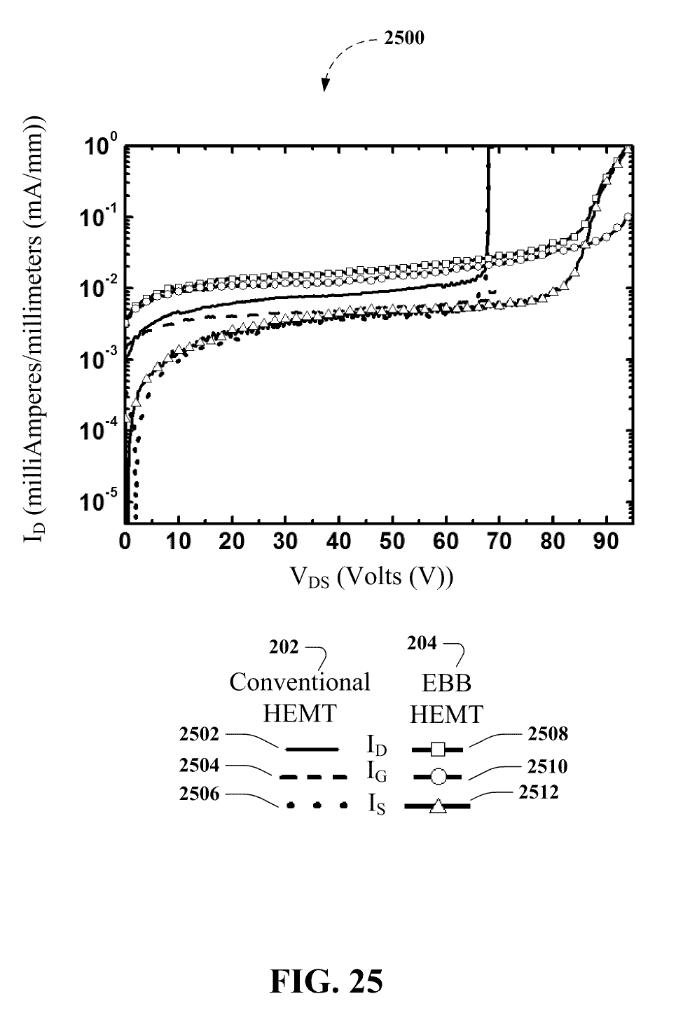

Conventional current voltage measurement and drain-current injection technique can be used to characterize the three-terminal off-state breakdown of the fabricated devices. FIG. 25 depicts comparison of off-state breakdown characteristics 2500 between a conventional 202 and EBB HEMTs 204 using conventional current-voltage measurements. As expected, larger BV_{off} is observed in EBB HEMT 204 as shown in FIG. 25. In the drain-injection test configuration, the drain injection current was fixed at 1 mA/mm, V_{GS} was swept down from 0 V to −25 V and I_{G}, V_{DS} and V_{DG} were recorded as a function of V_{GS}.

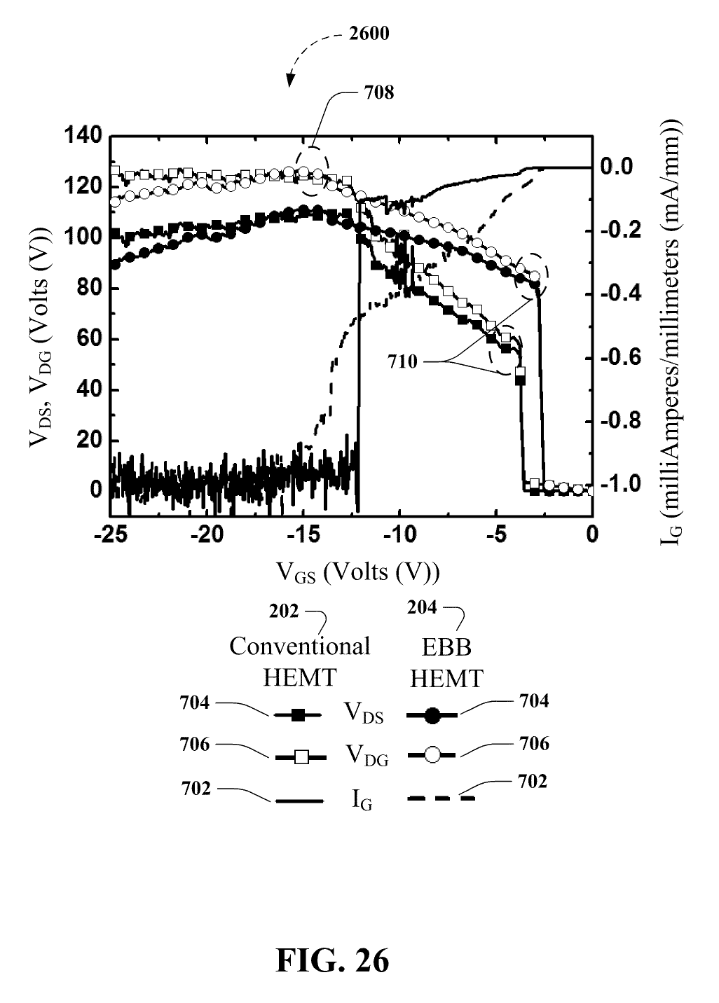

FIG. 26 depicts a comparison of three terminal off-state breakdown characteristics 2600 between a conventional AlGaN/GaN HEMT 202 and an EBB AlGaN/GaN HEMT 204 according to various aspects of the disclosed subject matter. Similar nomenclature and reference characters as in FIG. 7 are used, where I_{G} 702, V_{DS} 704, and V_{DG} 706 are depicted along with BV_{DG} 708, and BV_{DS} 710. Note that the parameters used for the comparison are L_{G} of 1 μm, L_{GS} of 1 μm, and L_{GD} of 2 μm. From FIG. 26, it can be seen that BV_{DS} of the premature three-terminal off-state breakdown is increased in EBB-HEMT 204 compared to the baseline HEMT 202, which is consistent with the result from the I-V measurement. A 38% improvement of the three-terminal BV_{off} is observed in an EBB AlGaN/GaN HEMT 204 with the improved blocking capability provided by the implanted fluorine 206, while the power figure of merit is increased by 40% from 32.4 to 46.4 MW/cm², despite the slight increase of on-resistance (Rₒₙ).

As a further example, FIG. 27 depicts an exemplary non-limiting electron potential energy distribution 2700 in the GaN buffer layer 104 as a function of relative position (X), for various depths 2702 under exemplary non-limiting HEMT gates 110/210, for a conventional AlGaN/GaN HEMT 202 and an EBB AlGaN/GaN HEMT 204 according to various aspects of the disclosed subject matter. The energy profiles from the source 108/208 side to the drain 112/212 side in EBB 204 and conventional HEMT 202 at different depths 2702 indicate that fluorine ions at the back of channel can effectively raise the local energy, providing a higher barrier compared to the conventional device 202.

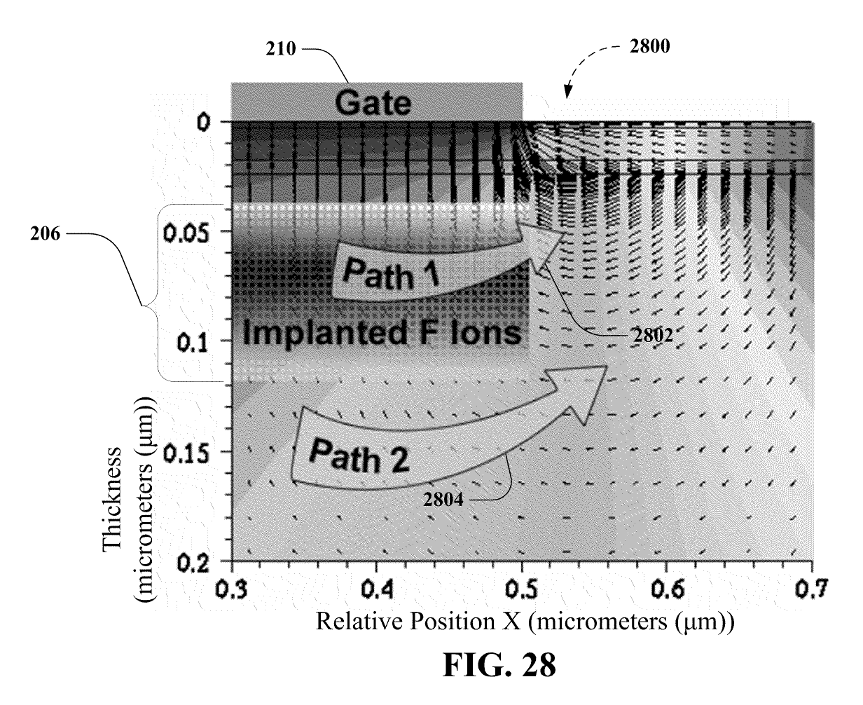

FIG. 28 depicts simulation results 2800 of exemplary off-state potential energy distribution and electric field vectors under an exemplary non-limiting gate region for comparison of a conventional AlGaN/GaN HEMT heterostructure 202 and an EBB AlGaN/GaN HEMT 204 according to various aspects of the disclosed subject matter. The simulation is conducted and illustrated with the Synopsys® Santaurus tool with V_{GS} and V_{DS} set at V_{T}−1 V and 60 V, respectively. Note that the simulated potential is depicted as a function of relative position X under the gate 210 and thickness of the i-AlGaN barrier layer 106 and i-GaN buffer layer 104 (e.g., the interface or heterojunction area) by grayscale shaded rays to denote the relative intensity of the simulated potential.

Further note that the electric field vectors in a conventional AlGaN/GaN HEMT 202 and an EBB AlGaN/GaN HEMT 204 are depicted by the grid of directional arrows. The EBB region or layer 206 is depicted as a gradient and is denoted as the implanted F ions. Path 1 2802 is intended to illustrate the source 208 (not shown) injected electrons' injection 114 path 2802 to the high-field region in a conventional AlGaN/GaN HEMT 202 (e.g., path 1 (902) in FIG. 9). Advantageously, as provided in the various embodiments of the disclosed subject matter, fluorine ions can be used to substantially block path 1 2802 in EBB AlGaN/GaN HEMT 204. As a result of the disclosed EBB region or layer 206 incorporation into the heterostructure, the source 208 (not shown) injected electrons 114 are directed to flow to drain 212 (not shown) via path 2 2804, avoiding the regions of peak electric field.

Thus, a higher three terminal off-state breakdown voltage can be achieved in EBB HEMTs 204, according to various aspects of the disclosed subject matter. It should be noted that the gate-injection induced breakdown voltage is the same in the two types of devices (e.g., conventional AlGaN/GaN HEMT 202 and an EBB AlGaN/GaN HEMT 204) as observed in FIG. 26 and that BV_{DG} reaches about 125 V in the gate-injection induced breakdown region in both type of devices. This indicates that the two types of device would have the substantially the same two-terminal off-state breakdown voltage. According to further embodiments of the disclosed subject matter, improvement of breakdown in such devices can be further achieved by reducing the peak electric field at the gate edge using field plates.

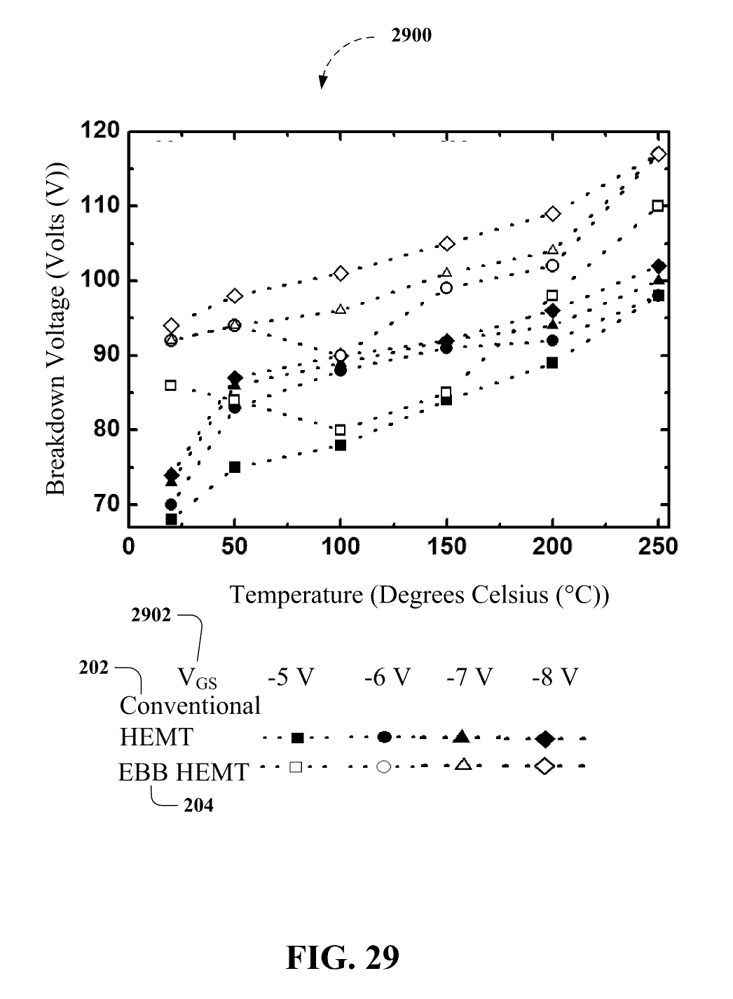

FIG. 29 depicts a comparison 2900 of temperature dependence of three terminal off-state breakdown voltage between a conventional 202 and an exemplary non-limiting embodiment of an EBB AlGaN/GaN HEMT 204. FIG. 29 depicts temperature dependence of the off-state breakdown voltage at different negative gate bias 2902, where BV_{off} of the exemplary EBB HEMT 204 at small gate 212 bias displays a negative temperature coefficient from room temperature to 100° C., indicating that the thermal emission over the back barrier 206 could affect breakdown. As temperature continues to rise, FIG. 29 depicts a positive temperature coefficient, the same as that in conventional HEMT 202, which is a typical signature of impact ionization. Thus, although thermal emission could be more significant at higher temperatures, the stronger phonon scattering would make it much harder for electrons to gain enough energy to initiate impact ionization.

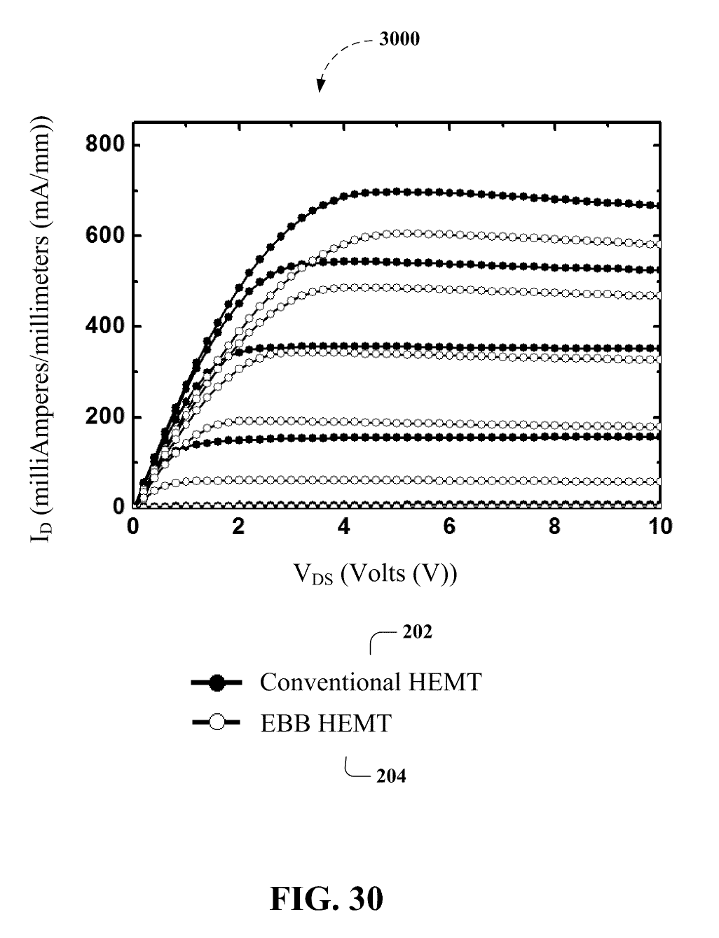

FIGS. 30 to 35 demonstrate the basic device characteristics of an EBB AlGaN/GaN HEMT heterostructure 204 according to various aspects of the disclosed subject matter, for which, FIG. 30 depicts I-V output 3000 with V_{GS} of 0.5 V to approximately −4.5 V and 1.5 V to approximately −3.5 V for a conventional AlGaN/GaN HEMT 202 and an EBB AlGaN/GaN HEMT 204, respectively, and with a step of −1 V. The DC characteristics of an exemplary EBB 204 and conventional HEMT 202 are shown in which the I-V curves were measured with the same gate swing from V_{T}−0.5 V. The small decrease in the maximum drain current and increase in Rₒₙ is a result of the reduction of electron mobility in the implanted region as described above.

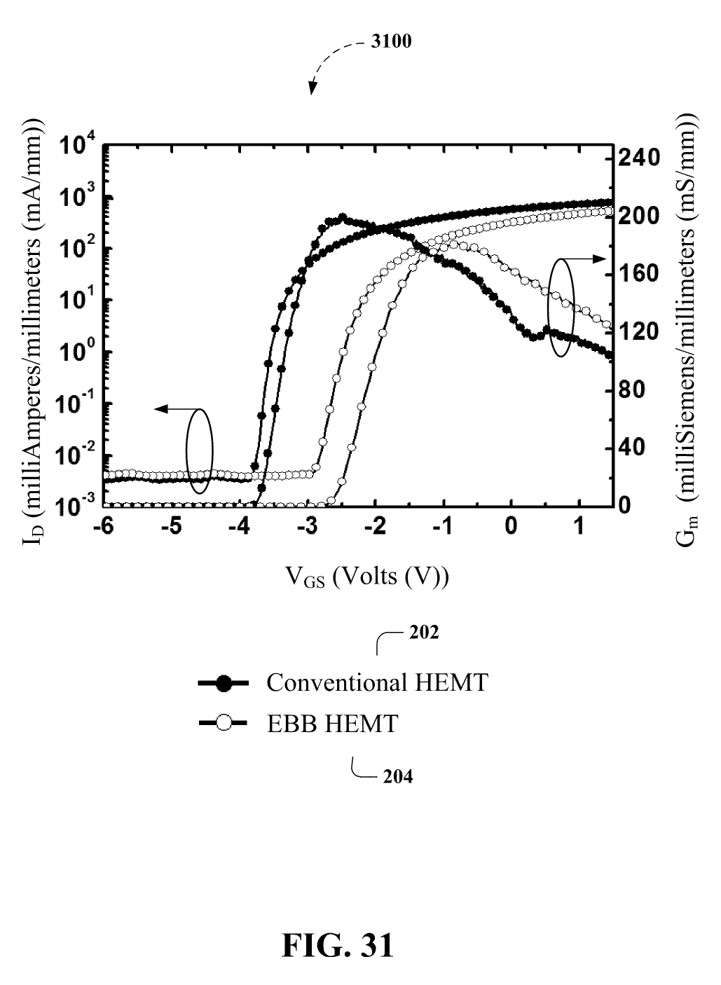

FIG. 31 depicts transfer characteristics 3100. Maximum transconductance of an exemplary EBB HEMT 204 is about 90% of a conventional HEMT 202, despite the fact that measured electron mobility is about 60% of the value in as-grown sample HEMT 202. Measured transconductance is in the saturation region, and thus, high field mobility can be considered, while the mobility deduced from Hall measurements indicates a low field one. This suggests that the high field mobility or the saturation velocity of electrons does not degrade significantly after fluorine ion implantation with post-implantation annealing, according to an aspect of the disclosed subject matter. In addition, for this particular embodiment, the source 208 access region was not implanted. As a result, the access resistance, which is an important factor in determining the extrinsic transconductance, does not suffer from any degradation. Pulse measurements can be performed to investigate the possible trapping effect after fluorine ion implantation in EBB HEMT 204.

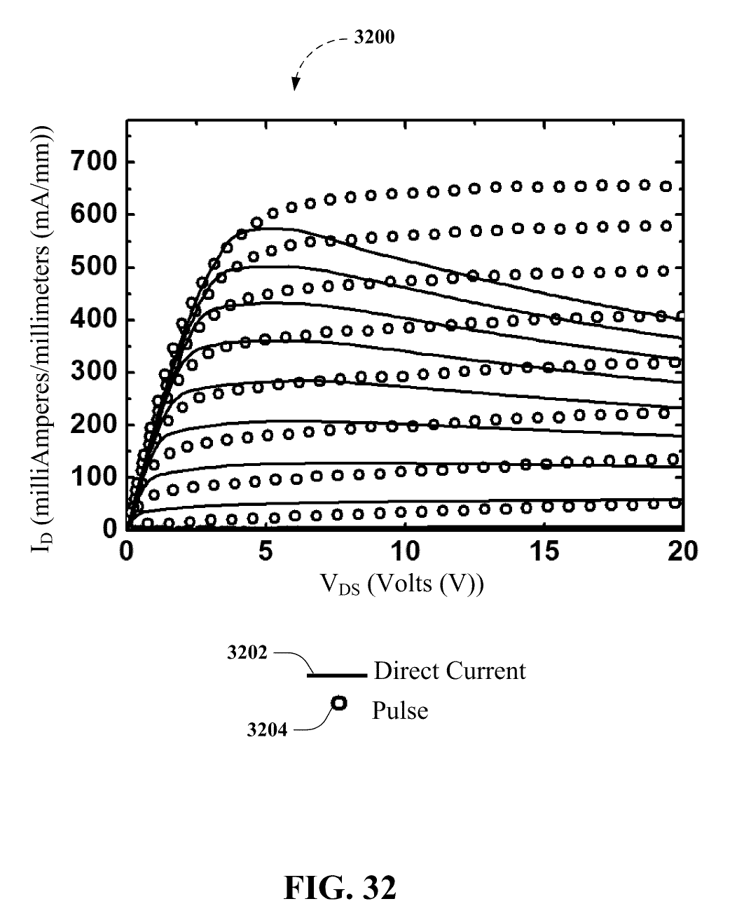

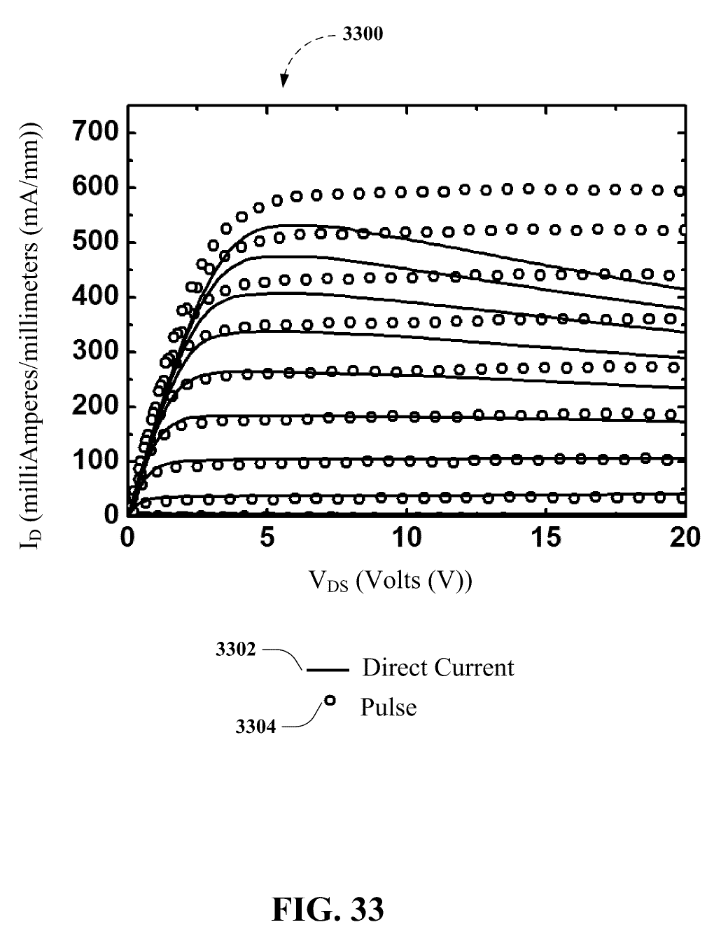

Accordingly, FIG. 32 depicts DC and pulsed I-V characteristics 3200 of exemplary SiN passivated 1×100 μm conventional HEMT 202. The quiescent biases for the pulsed I-V measurement are V_{GS0} of V_{T}−1 V and V_{DS0} of 20 V. FIG. 33 depicts DC and pulsed I-V characteristics 3300 of exemplary SiN passivated 1×100 μm EBB HEMTs 204, respectively. With respect to FIGS. 32 and 33, the gate swing V_{GS} is −4.5 V to approximately 0.5 V and −3.5 V to approximately 1.5 V for a conventional AlGaN/GaN HEMT 202 and an EBB AlGaN/GaN HEMT 204, respectively, and with a step of 0.5 V, and pulse width of 2 microseconds (μs) and a separation of 1 millisecond (ms). No degradation in pulse measurement 3304 is observed in EBB HEMT 204, which indicates that any trapping effect induced by fluorine ion implantation is not a substantial detriment, perhaps owing in part to the relatively low dose selected for fluorine implantation. In addition, fluorine ions at the back of the channel effectively raises the energy barrier in the GaN buffer 104 and tend to prevent electrons being trapped by the defects induced by implantation. On-wafer bias-dependent small-signal S-parameters measurements were conducted on 1×100 μm EBB and conventional HEMTs, using a Hewlett-Packard® HP4142B modular DC source/monitor and an Agilent® 8722ES network analyzer with cascade microwave probes, though such instruments and details are to be considered non-limiting.

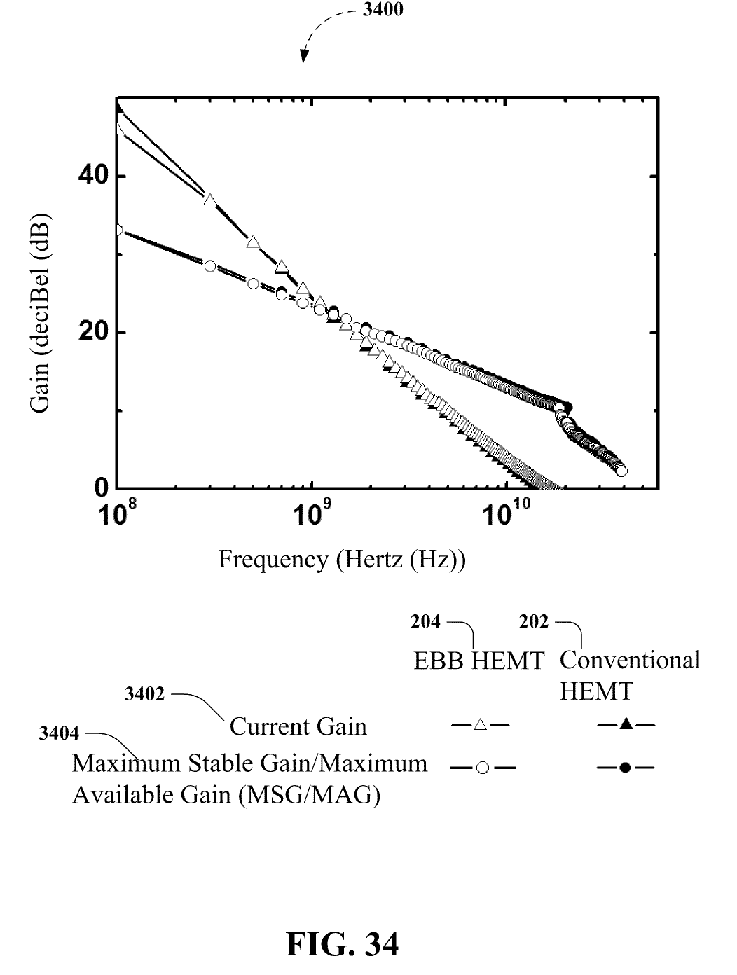

FIG. 34 depicts maximum current gain 3402 and maximum stable gain 3404 for the exemplary devices having a 1 μm long gate 110/210 as a function of frequency up to 39 GHz.

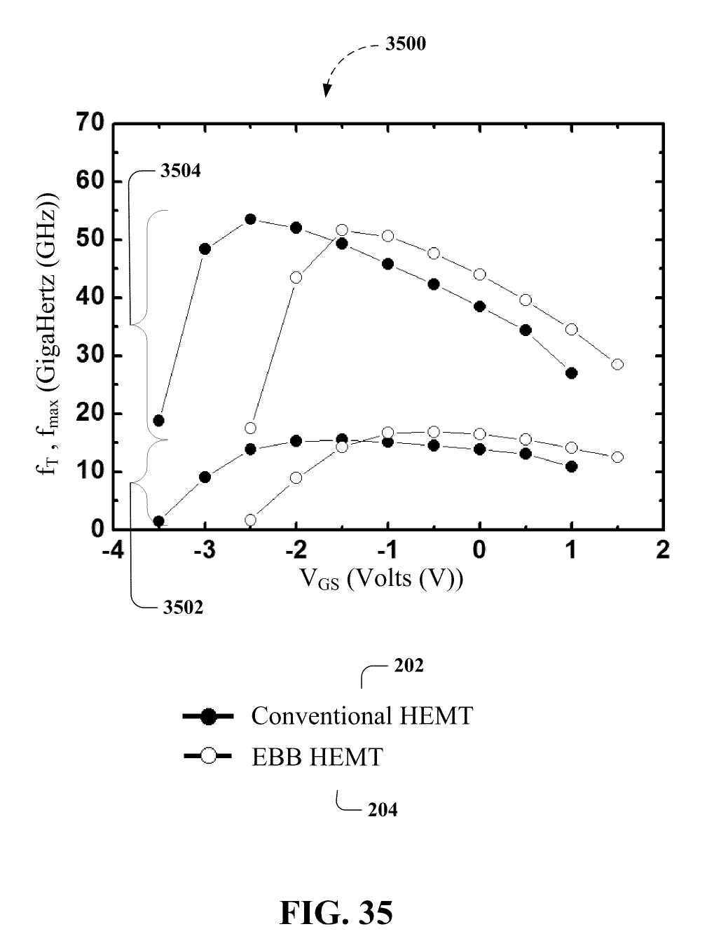

FIG. 35 depicts cut-off frequencies 3500 for a conventional AlGaN/GaN HEMT 202 (3502) and an EBB AlGaN/GaN HEMT 204 (3504). Note that the parameters used for the comparison are L_{G} of 1 μm, L_{GS} of 1 μm, and L_{GD} of 2 μm in the bias-dependent current gain cutoff frequency (f_{T}) and power gain cutoff frequency (fₘₐₓ) with the drain voltage fixed at 10 V. The peak fₜ is about 15 GHz and peak fₘₐₓ is about 50 GHz. No obvious degradation of the RF performance is observed in the exemplary EBB HEMT 204.

From FIGS. 30 to 35, it can be seen that there is minor degradation in the on-resistance, maximum drain current, and peak transconductance. Advantageously, no obvious degradation is observed in Radio Frequency (RF) characteristics 3500, indicating no degradation in the saturation velocity.

### Further Non-Limiting Embodiments of AlGaN/GaN EBB HEMTs

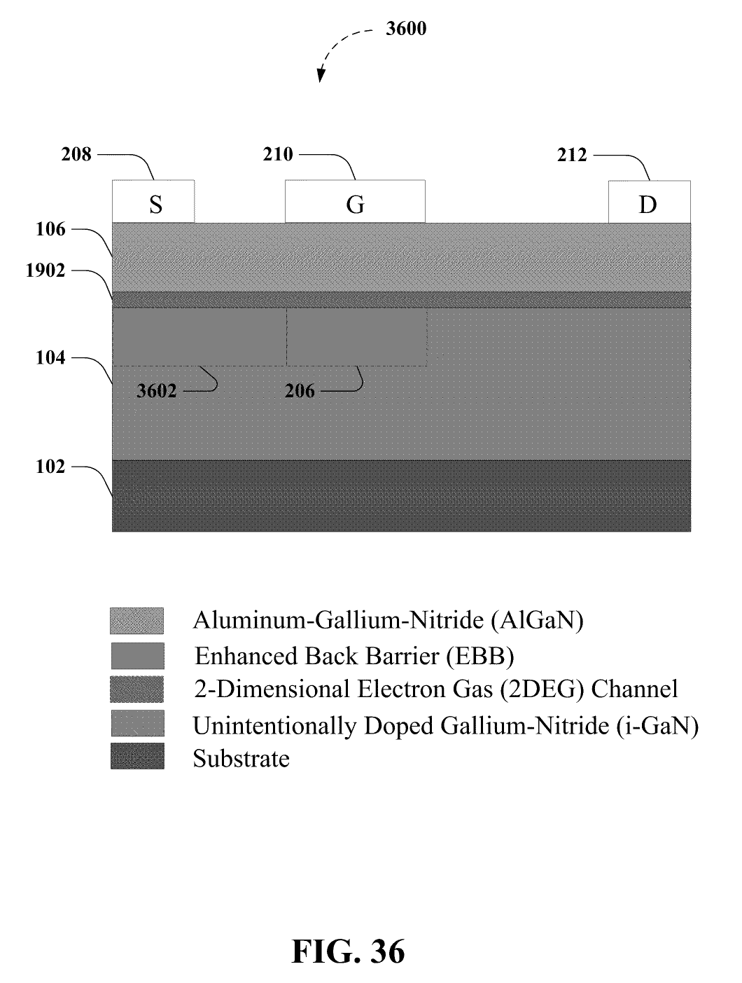

FIGS. 36 to 41 illustrate further non-limiting embodiments, according to various aspects, and relative benefits of the disclosed embodiments, in which FIG. 36 depicts a schematic cross section of an exemplary non-limiting embodiment 3600 of an EBB AlGaN/GaN HEMT 204 with fluorine ions implanted 206 to improve the off-state breakdown voltage by enhancing the back barrier 206 and to reduce the source leakage current (e.g., via implant region 3602). The enhanced back barrier 206 can also reduce the source 208 leakage current from the underlying GaN buffer layer 104 in an AlGaN/GaN HEMT 204. For example, fluorine ions can be implanted in the region from the source 208 to gate 210 edge (implant region 3602). The enhanced back barrier in this region 3602 separates the source contact 208 from the underlying GaN buffer 104, which can reduce the leakage current from the imperfect GaN buffer layer 104.

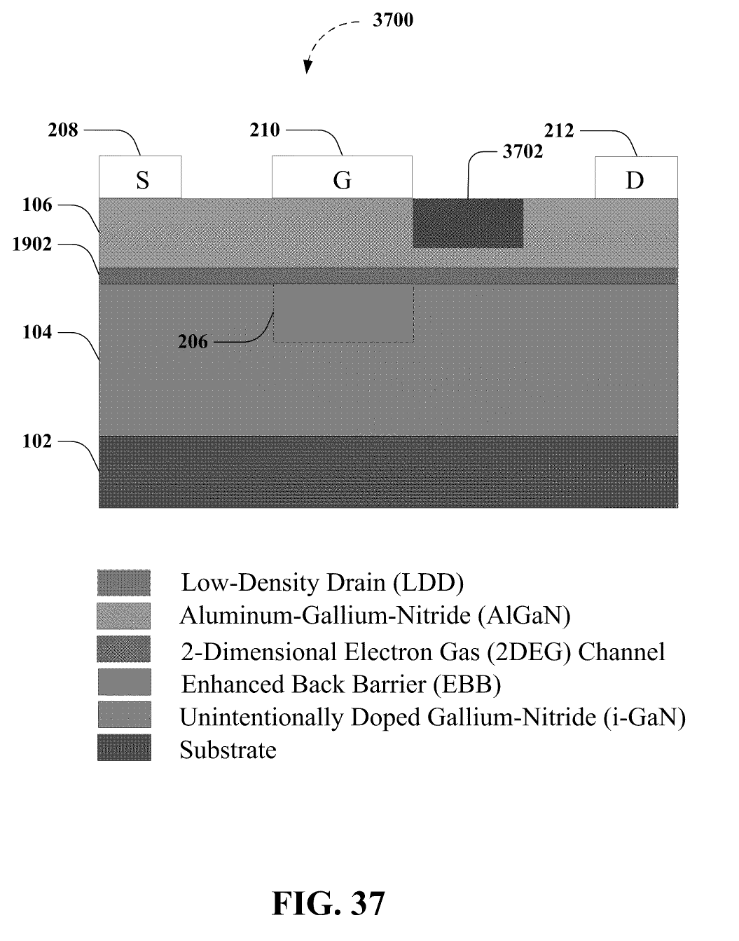

In a further aspect of the disclosed subject matter, a low-density drain (LDD) can also be integrated into such device (e.g., EBB HEMT 3600) to further reduce the peak electric field and enhance the breakdown voltage as described with respect to the embodiments depicted in FIGS. 37-42.

For example, it has been shown that higher breakdown voltage and reduced current collapse can be achieved in LDD AlGaN/GaN HEMTs using a fluorine plasma treatment. For example, electronegative ion-based (e.g., fluorine-based) plasma treatment or low-energy ion implantation can be used to modify the drain-side surface field distribution, e.g., creating a LDD, without the use of a field plate electrode. As a result, off-state breakdown voltage can be improved and current collapse can be substantially suppressed in a LDD-HEMTs with no significant degradation in gains and cutoff frequencies. Accordingly, the disclosed subject matter provides additional structures and devices using fluorine ion implantation to improve the breakdown voltage in AlGaN/GaN HEMTs, which combine an EBB region or layer 206 and a LDD to further improve AlGaN/GaN HEMT's performance.

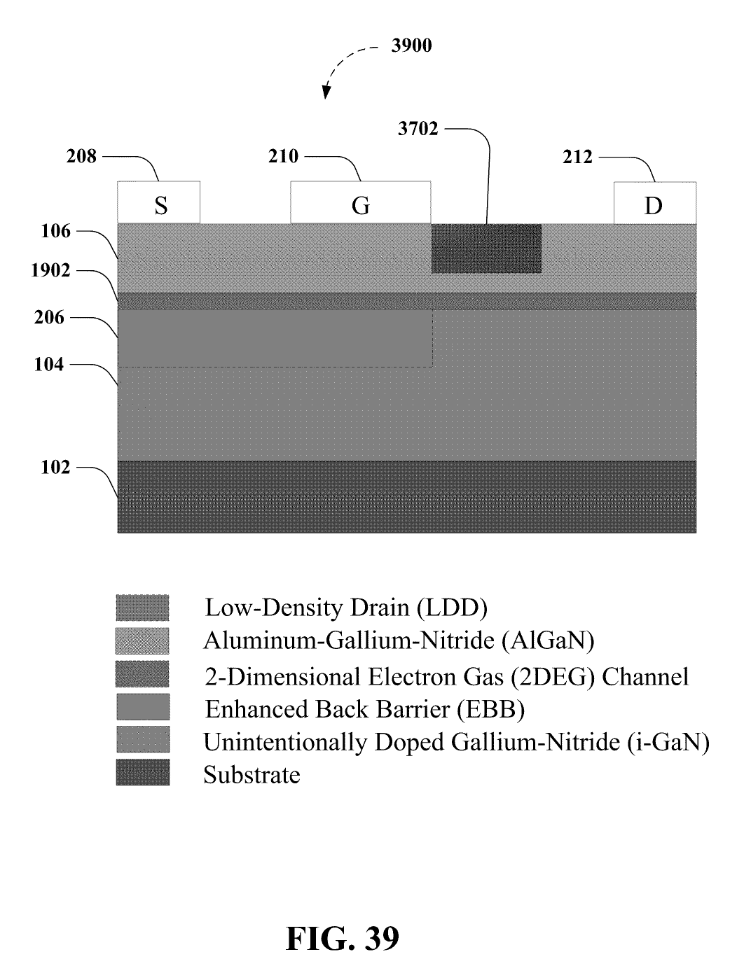

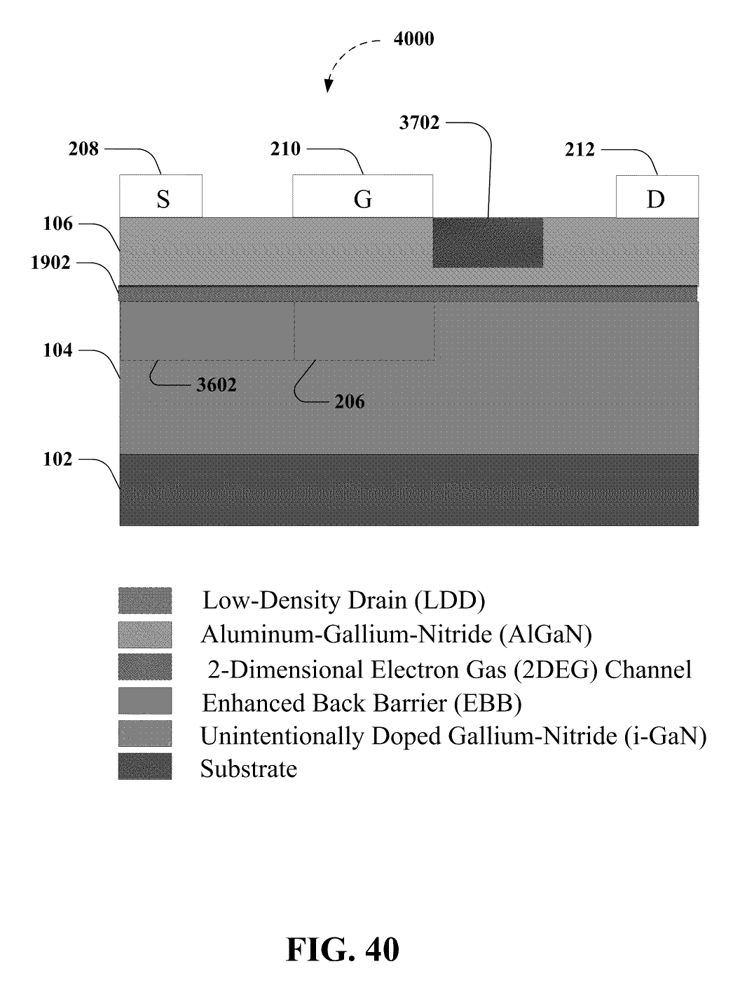

To that end, FIG. 37 depicts an exemplary embodiment 3700 comprising a combination of an EBB 206 and a LDD 3702 (e.g., an EBB/LDD HEMT). FIGS. 39 and 40 depict further non-limiting embodiments 3900 and 4000 of EBB/LDD HEMTs, incorporating aspects and advantages from exemplary embodiments 3600 and 3700 of FIGS. 36 and 37, respectively. As shown, an EBB 206 can be integrated with a LDD 3702 to further improve off-state breakdown voltage. In various embodiments, the LDD region can be formed using low energy ion implantation or fluorine plasma treatment.

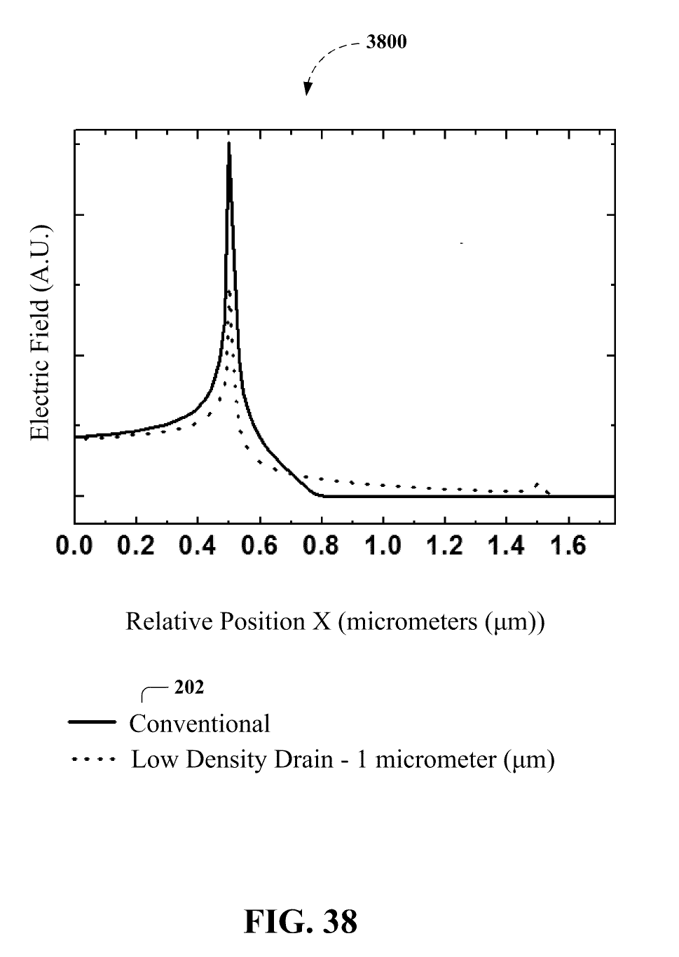

Referring again to FIG. 37, the figure depicts an exemplary embodiment 3700 of the disclosed subject matter comprising a combination of an EBB 206 and a LDD 3702 (e.g., an EBB/LDD HEMT) AlGaN/GaN HEMT, where anticipated electric field distribution before and after the formation of LDD 3702 using fluorine treatment is depicted 3800 in FIG. 38. As can be understood by one skilled in the art, this exemplary non-limiting embodiment 3700 advantageously combines the EBB region or layer 206, providing improved blocking capability, while the LDD region can redistribute the electric-field profiles between the gate 210 and drain 212.

It can also be appreciated that all or part of the region between gate 210 and drain 212 can be transformed into a region with a low density 2DEG using a plasma treatment, low-energy ion implantation, etc. (e.g., a carbon tetrafluoride CF₄ plasma treatment, treatment with a gas including CF₄, sulfur hexafluoride (SF₆), boron difluoride (BF₂), and combinations thereof, thermal diffusion etc.) to form a LDD 3702 on a HEMT heterostructure 204. For instance, after the windows of a low-density drain region are defined, a CF₄ plasma treatment under an RF source power of 150 Watts (W) can be applied for 45 seconds. The LDD HEMT 3700 can then be annealed at 400 degrees Celsius for 10 minutes.

As further examples, FIGS. 39 and 40 depict additional non-limiting embodiments of AlGaN/GaN EBB/LDD HEMTs (3900/4000) that can reduce the off-state drain leakage current and improve the breakdown voltage characteristics by incorporating an EBB region or layer 206 that extends or reaches substantially all the way to the source 208 region. For example, by extension of the EBB region or layer 206 in FIG. 39, the HEMT 3900 can reduce off-state drain leakage current, by creating a local blocking region via fluorine ion implantation. Note that in FIGS. 36 and 40-41, the EBB regions or layers extending to the source 208 region are depicted as comprising separate fluorine implanted regions 3602 and 206, whereas FIG. 39 depicts one region or layer 206 extending to the source 208 region to reduce off-state drain leakage current. It can be appreciated that either approach (e.g., separate formation of regions 206 and 3602, or formation of an extended region 206) can accomplish the objective of reducing off-state drain leakage. However, the flexibility of the disclosed subject matter allows the structures of FIGS. 36, and 40-41 to achieve somewhat independently tailored objectives (e.g., improving breakdown voltage and reducing source leakage current), whereas the structures of FIG. 39 can allow for economy of processing (e.g., implant of fluorine in both locations 206 and 3602 of FIG. 36 substantially in the same process steps).

As described above, similar to the discussion regarding fluorine concentration in reference to FIGS. 2-3, and 22, although the EBB region or layer 206 (and 3602) in FIGS. 36-37 and 39-42 are depicted as discretely and homogenously shaded regions to indicate the presence of the implanted fluorine ion concentration, the actual concentration profile, according to various embodiments, can be a continuum or gradient of fluorine concentrations in the EBB region or layer 206 (3602), as shown as and described with reference to FIGS. 3 and 22. It should be pointed out that the LDD region 3702, as depicted in 3700 (as well as 3900, 4000, 4100, and 4200), corresponds to a fluorine treated region suitable for constructing an operative LDD in an AlGaN/GaN EBB/LDD HEMT as can be appreciated by one of ordinary skill in the art.

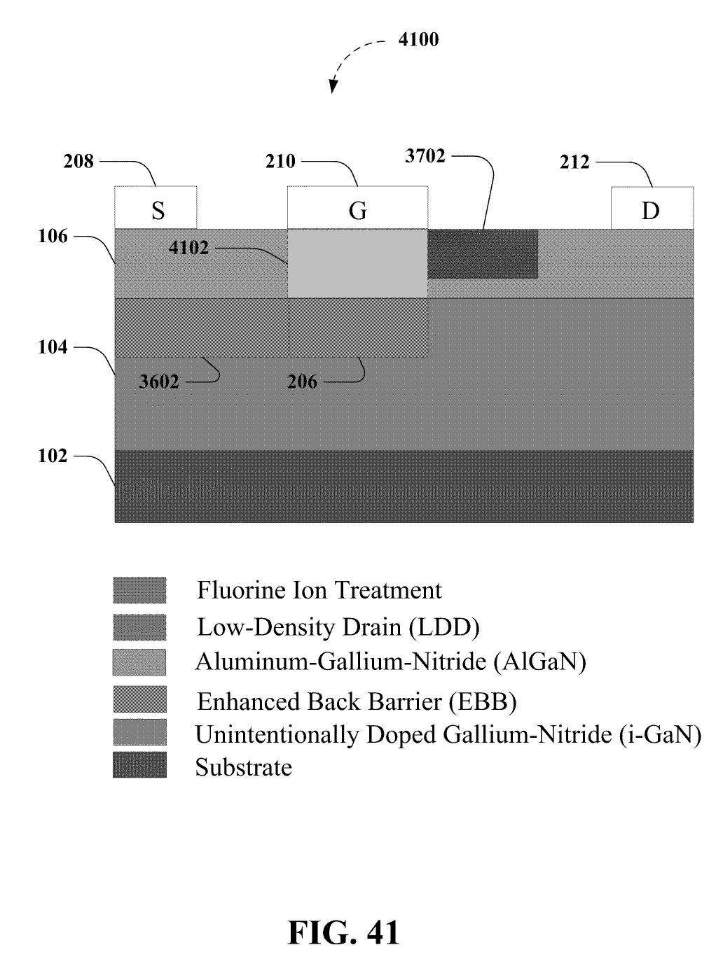

FIG. 41 depicts a schematic cross section of an exemplary enhancement mode AlGaN/GaN HEMT 4100 with enhanced back barrier 206 in the region under the gate 210 and in the region from the source 208 to the gate 210 edge 3602. Advantageously, the combination of enhanced back barrier 206/3602 and low density drain 3702 can reduce the source leakage current and improve the off-state breakdown voltage. In this particular embodiment, fluorine ions can be used to fabricate an enhancement-mode AlGaN/GaN HEMT 4100 (e.g., MESFET, MISFET, HEMT, MISHEMT, etc.) with low source leakage current and high breakdown voltage. Enhancement mode operation can be achieved by incorporation of negatively charged fluorine ions into the AlGaN layer 106 under the gate 210 region 4102. Note that fluorine ions in the AlGaN layer 106 under the gate region 4102 can either be implanted by fluorine plasma treatment or low energy ion implantation, or another suitable alternative. Enhanced back barrier 3602 from the source 208 to the gate 210 edge and under the gate region 206 can be implemented as described above, as can low density drain region 3702.

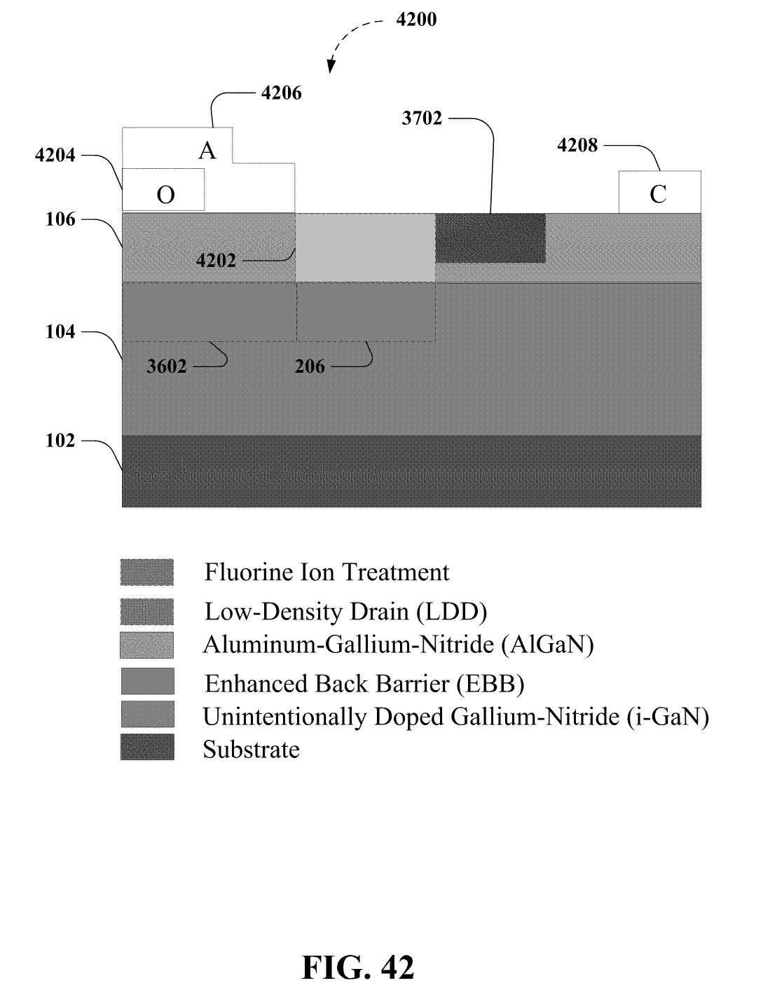

FIG. 42 depicts a schematic cross section of an exemplary non-limiting embodiment of a lateral field-effect rectifier 4200 according to various aspects of the disclosed AlGaN/GaN heterostructures, with EBB(s) 206/3602, and a LDD 3702 similar to that described above. In addition, lateral field-effect rectifier 4200 can include a fluorine ion treated region 4202 disposed in the AlGaN layer 106 under similar to that described for fluorine ion treated region 4102 of FIG. 41. Fluorine ion treated region 4202, can be disposed between the regions below an ohmic contact/anode structure (4204/4206) and a cathode 4208, and in particular, between the LDD 3702 and the region below an ohmic contact/anode structure (4204/4206).

Further development of such heterostructures is described in connection with the various non-limiting embodiments as follows. The concept of creating a local blocking region via fluorine implantation can be implemented in device structures that typically employ blocking structures, such as in an AlGaN/GaN vertical heterostructure field-effect transistors (V-HFET). While V-HFET implementations have typically used Magnesium (Mg) implantation followed by an expensive re-growth process, as described above, the provided structures and devices can be created by selectively implanting fluorine ions in developing structures (e.g., post-epitaxial growth).

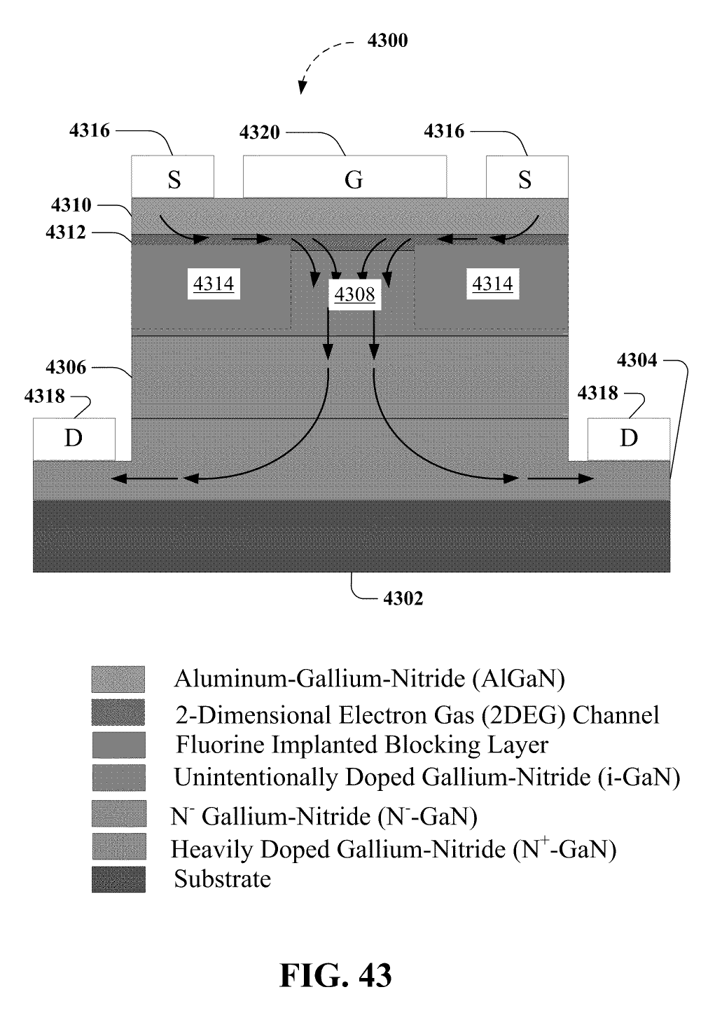

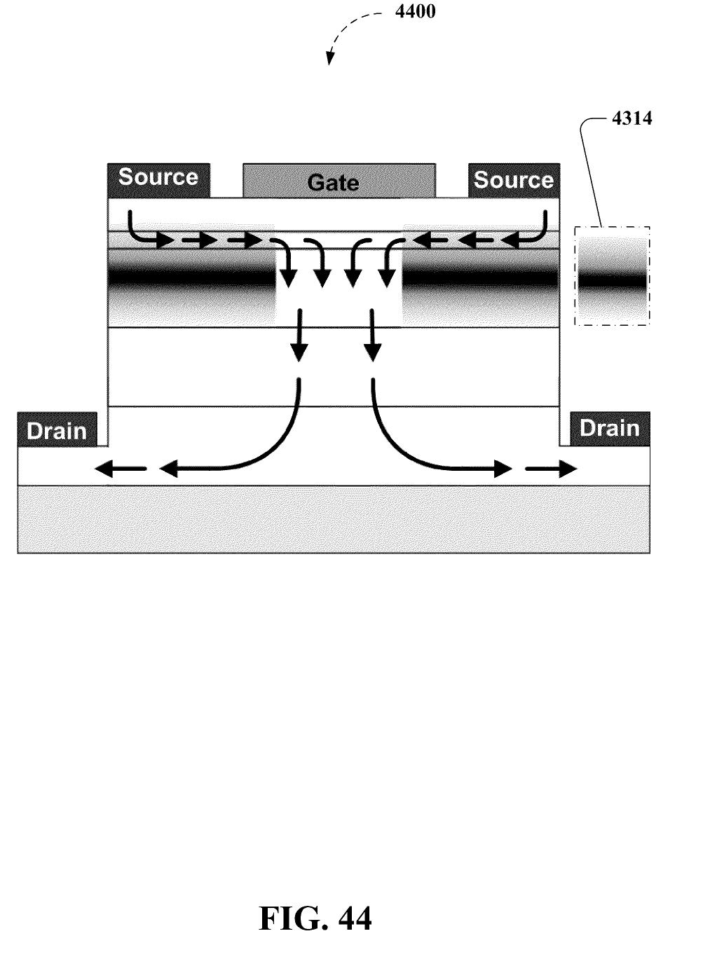

FIGS. 43 to 44 depict a cross section of an exemplary non-limiting AlGaN/GaN vertical heterostructure field-effect transistor 4300 and 4400 with a fluorine implanted source-drain blocking region or layer according to various aspects of the disclosed subject matter. Advantageously, the described fluorine ion implantation operation is made available by commercial ion implantation providers, and the provided structures and devices can be created by selectively implanting fluorine ions in developing structures (e.g., post-epitaxial growth), which can avoid the expensive re-growth process. The provided structures are expected to improve source-drain isolation in the off-state by virtue of a fluorine implanted blocking region or layer.

FIG. 43 depicts an AlGaN/GaN V-HFET 4300 comprised of a substrate 4302, upon which heavily doped GaN (N⁺-GaN) 4304, GaN (N⁻-GaN) 4306, and an i-GaN/AlGaN (1608/1610) heterojunction is formed creating the 2DEG 4312 channel. Fluorine ions can be implanted to create the fluorine implanted blocking region or layers 4314, which can serve to improve source 4316 to drain 4318 isolation in the off-state of the AlGaN/GaN V-HFET 4300. The arrows traveling from the source pads 4316 through 2DEG 4312 around blocking layers or regions 4314 to the drain pads 4318 in FIGS. 43 and 44 are intended to indicate the expected electron flow as a result of the fluorine implanted blocking regions or layers 4314, according to various aspects of the disclosed subject matter.

As described above, similar to the discussion regarding fluorine concentration in reference to FIGS. 2, 3, 22, 19, 37, and 39, although the fluorine implanted blocking region or layer 4314 in FIG. 43 is depicted as a discretely and homogenously shaded region to indicate the presence of the implanted fluorine concentration, the actual concentration profile, according to various embodiments, can be a continuum of fluorine concentrations in the fluorine implanted blocking region or layer 4314, similar to that shown (although not necessarily the same concentration, position, dose, etc.) and described with reference to FIGS. 3 and 22. For example, the blocking region or layer 4314 of 4300 is more accurately depicted as a continuum or gradient of fluorine concentrations in the blocking region or layer 4314 in 4400 of FIG. 44, rather than as sub-regions of discrete concentrations.

Additionally, while the 2DEG Channel 4312 is depicted as a discrete region adjacent to and between the AlGaN layer 4310 and the i-GaN layer 4306, 2DEG Channel 4312 is comprised of a narrower-bandgap channel at the heterojunction created due to the different band-gap materials forming an electron potential well in the conduction band on the non-doped side of the heterojunction.

Moreover, the ion energy and dose, as well as location, concentration profile, etc. as further described above, of the blocking region or layer 4314 can be adjusted for different requirements of the fluorine distribution. Accordingly, such embodiments should not be limited by any of the other exemplary non-limiting embodiments as described herein.

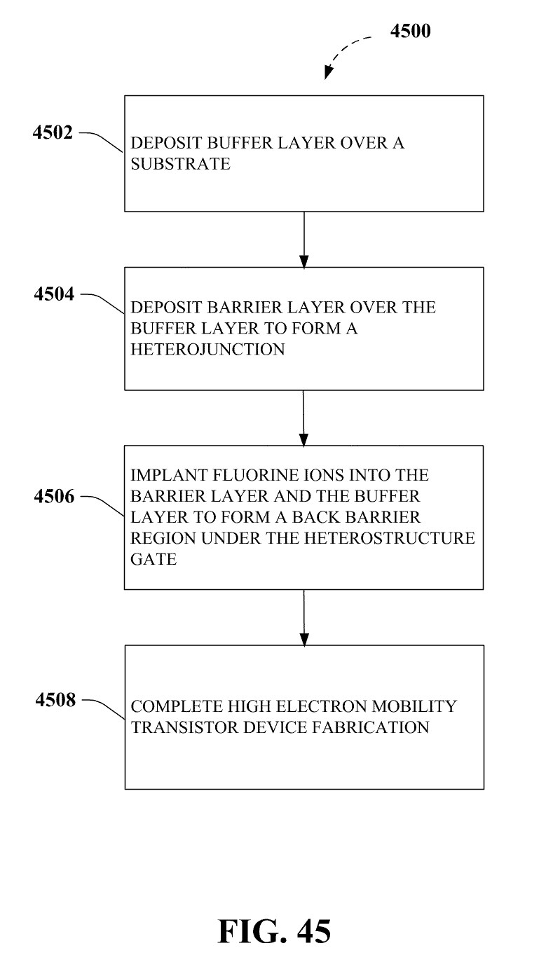

In view of the structures and devices described supra, methodologies that can be implemented in accordance with the disclosed subject matter will be better appreciated with reference to the flowchart of FIG. 45. While for purposes of simplicity of explanation, the methodologies are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methodologies described hereinafter.

### Exemplary Methodologies

FIG. 45 depicts exemplary non-limiting methodologies for forming a back barrier region in a high electron mobility transistor (e.g., an EBB AlGaN/GaN HEMT 204, 1800, 1900, 3600, 3700, 3900, 4000, 4100, 4200, 4300, etc.) in accordance with aspects of the disclosed subject matter. As can be appreciated, variations in the exemplary methodologies known to one having ordinary skill in the art may be possible without deviating from the intended scope of the subject matter as claimed.

For instance, at 4502, a buffer layer (e.g., 104) can be deposited over a suitable substrate (e.g., 102). For example, as described above, suitable substrates can comprise sapphire, silicon (111), silicon carbide, aluminum nitride (AlN), or GaN, or any combination thereof and can include a nucleation layer comprised of GaN or AlN to facilitate epitaxial crystal growth of the buffer layer. As a further example, the buffer layer 104 (e.g., unintentionally doped GaN) can be grown through an epitaxial crystal growth method (e.g., MOCVD, MBE, etc.).

Likewise, at 4504, a barrier layer (e.g., 106) can be deposited over the buffer layer 104 to form a heterojunction at the interface with barrier layer 106 and the buffer layer 104. As with the buffer layer 104, the barrier layer 106 (e.g., AlGaN) can be grown through an epitaxial crystal growth method (e.g., MOCVD, MBE, etc.).

In one non-limiting embodiment of the disclosed subject matter, the heterostructure can comprise 2 μm of unintentionally doped GaN (i-GaN) buffer layer 104 grown on a common substrate 102 of sapphire, upon which is grown a 24 nm barrier layer 106 of unintentionally doped AlGaN (i-AlGaN) (e.g., i-Al_{0.25}Ga_{0.75}N).

At 4506, a back barrier region or layer 206 can be formed by implanting fluorine ions into the buffer layer 104. For example, the fluorine ions can be implanted under the design or prospective location for the heterostructure gate 210, during the HEMT fabrication process post-growth, and in some cases, before further processing continues. This location for implantation is chosen as gate 210 is typically fabricated at a later step (not shown), which according to various aspects of the disclosed subject matter, is to be located substantially over the back barrier region or layer 206 (e.g., an enhanced back barrier in accordance with the disclosed subject matter).

In addition, implanting fluorine ions can be performed to achieve a peak fluorine concentration located in the buffer layer 104 adjacent to the heterojunction or interface (e.g., under the 2DEG channel 1902). In one non-limiting methodology, fluorine-19 ions can be implanted with a selected energy (e.g., 50 keV) at a selected dose (e.g., 1×10¹² cm⁻²) using an ion implanter (e.g., a Varian CF3000). In a further non-limiting methodology, fluorine ions can be implanted into the buffer layer 104 to form the back barrier region 206 under the design location of the HEMT gate 210 and reaching to a region under the design location of the HEMT source 208.

In addition, methodologies 4500 can include steps preparatory to, or for completing, the HEMT device fabrication process, 4508. As an example, steps preparatory to HEMT fabrication can include processes to facilitate isolation between different devices for example, by mesa etching (e.g., by inductively coupled plasma reactive ion etching), ion implantation, etc. For example, in the disclosed AlGaN/GaN EBB/LDD HEMTs, a low density drain 3702 structure can be formed, as described above, if not formed prior to this point in the fabrication process (e.g., prior to back barrier region 206 formation). For instance, a region of fluorine 3702 can be formed adjacent to the design location of the HEMT gate 210 and between the design location of the HEMT gate 210 and the design location of the HEMT drain 212.

As another example, fluorine ions can be used to fabricate an enhancement-mode AlGaN/GaN HEMT 4100, which can be achieved by incorporation of negatively charged fluorine ions into the AlGaN layer 106 under the gate 210 region 4102. For instance, fluorine ions in the AlGaN layer 106 under the gate region 4102 can either be implanted by fluorine plasma treatment or low energy ion implantation, or using another suitable alternative. In addition, steps necessary to create a lateral field effect transistor can be performed as described above.

As a further example, additional resist strip, etch, clean, or other process steps (not shown) may be desired or required post-implant, depending on the design of the HEMT fabrication process. Also, additional process steps (not shown) may be employed to complete fabrication of the source 208, gate 210, drain 212, etc. in order to complete fabrication of a useable device (e.g., either in isolation, or as part of an integrated circuit).

For example, a typical process of fabricating a Group III-nitride heterostructure field-effect transistor (HFET) comprises an epitaxial structure (e.g., substrate 102, buffer layer 104, and a barrier layer 106), where the buffer layer 104 can be grown over a substrate, facilitated by a nucleation layer (e.g., low temperature grown GaN nucleation layer, AlGaN or AlN, etc.). A mesa isolation can be formed using a Cl₂/He plasma dry etching followed by source/drain ohmic contact formation with Ti/Al/Ni/Au annealed at 850 degrees Celsius for 30 seconds. Subsequently, photoresist can be patterned with the gate windows exposed. The gate electrode can be formed on the barrier layer by depositing and lift-off Ni and Au (e.g., with or without a dielectric insulator under the gate metal, or other variations, etc.). Thereafter, post-gate rapid thermal annealing (RTA) can be conducted at 400 to 450 degrees Celsius for 10 minutes. A passivation layer (e.g., SiN, silicon oxide(SiO), polyimide, Benzocyclobutene (BCB), etc.) can then be grown on top of the device. Finally, the contact pads can be opened by removing portions of the passivation layer on the contact pads.

Further non-limiting embodiments of methodologies 4500 (not shown) can include process steps to create a AlGaN/GaN V-HFET comprised of a substrate 4302, upon which heavily doped GaN (N⁺-GaN) 4304, GaN (N⁻-GaN) 4306, and an i-GaN/AlGaN (1608/1610) heterojunction is formed creating the 2DEG 4312 channel. As an example, fluorine ions can be implanted to create the fluorine implanted blocking region or layers 4314, which can serve to improve source 4316 to drain 4318 isolation in the off-state of the AlGaN/GaN V-HFET 4300, as more fully described above.

While the disclosed subject matter has been described in connection with the preferred embodiments of the various figures, it is to be understood that other similar embodiments may be used or modifications and additions may be made to the described embodiments for performing the same function of the disclosed subject matter without deviating therefrom. For example, one skilled in the art will recognize that aspects of the disclosed subject matter as described in the various embodiments of the present application may apply to other Group III-Nitride heterostructures, other insulating or semiconducting materials or substrates, etc.

As a further example, in addition to the disclosed buffer layer 104 and barrier layer 106, it is conceivable that other layers for purposes other than described in one or more embodiments herein can be introduced between the buffer layer 104 and barrier layer 106. However, in such cases, such intermediate layers, without effect, can be considered as part of the buffer layer 104 or part of the barrier layer 106. Moreover, sometimes layers inadvertently introduced (e.g., process contaminants, oxidation, natural impurities, etc.) are also formed as a byproduct of an industrial fabrication process and such layers also are not to be considered separate layers.

In other instances, variations of process parameters (e.g., dimensions, configuration, concentrations, concentration profiles, implant energies and doses, process step timing and order, addition and/or deletion of process steps, addition of preprocessing and/or post-processing steps, etc.) may be made to further optimize the provided structures, devices and methodologies, as shown and described herein. In any event, the structures and devices, as well as the associated methodologies described herein have many applications in high electron mobility transistor heterostructures. Therefore, the disclosed subject matter should not be limited to any single embodiment described herein, but rather should be construed in breadth and scope in accordance with the appended claims.

What is claimed is:

1. An aluminum gallium nitride/gallium nitride (AlGaN/GaN) high electron mobility transistor (HEMT), the HEMT having prospective locations for a source, a gate, and a drain, the HEMT comprising:
a substrate;
a buffer layer comprising gallium nitride (GaN) disposed on the substrate;
a barrier layer comprising aluminum gallium nitride (AlGaN) disposed on the buffer layer and forming a heterojunction at an interface of the barrier layer and the buffer layer; and
an enhanced back barrier (EBB) region of implanted fluorine disposed within the buffer layer and spanning a portion of the heterojunction.

2. The AlGaN/GaN HEMT of claim 1, the substrate comprising at least one of sapphire, silicon (111), silicon carbide (SiC), aluminum nitride (AlN), or GaN.

3. The AlGaN/GaN HEMT of claim 1, the buffer layer is disposed on the substrate over a nucleation layer comprised of GaN or AlN.

4. The AlGaN/GaN HEMT of claim 1, the EBB region of implanted fluorine is located in a region of the heterostructure under the prospective location for a gate of the heterostructure.

5. The AlGaN/GaN HEMT of claim 1, the implanted fluorine comprises implanted Fluorine-19 ions delivered to the heterostructure with an energy and at a dose substantially equivalent to 50 kilo electron Volts and 10¹² ions per square centimeter.

6. The AlGaN/GaN HEMT of claim 1, the implanted fluorine comprises a peak fluorine concentration located in the buffer layer adjacent to the interface.

7. The AlGaN/GaN HEMT of claim 1, the substrate comprises sapphire, the buffer layer comprises unintentionally doped GaN, and the barrier layer comprises one of unintentionally or intentionally doped AlGaN.

8. The AlGaN/GaN HEMT of claim 7, the buffer layer comprises approximately 2 micrometers of unintentionally doped GaN, and the barrier layer comprises approximately 24 nanometers of unintentionally doped AlGaN.

9. The AlGaN/GaN HEMT of claim 1, further comprising:
a low density drain region of fluorine adjacent to the prospective location for the gate of the HEMT and between the prospective location for the gate of the HEMT and the prospective location for the drain of the HEMT.

10. The AlGaN/GaN HEMT of claim 9, the EBB region of implanted fluorine is located in a region under the prospective location for the gate of the HEMT and extends substantially towards a region under the prospective location for the source of the HEMT.

11. An Aluminum Gallium Nitride/Gallium Nitride (AlGaN/GaN) vertical heterostructure field-effect transistor (V-HFET) structure, comprising:
an unintentionally doped gallium nitride (GaN) layer;
an aluminum gallium nitride (AlGaN) layer disposed on the GaN layer and forming a heterojunction at an interface of the AlGaN layer and the GaN layer; and
at least one fluorine implanted blocking region disposed within the GaN layer and extending across a portion of the heterojunction.

12. The AlGaN/GaN V-HFET structure of claim 11, the at least one fluorine implanted blocking region comprises a peak fluorine concentration located in the GaN layer adjacent to the interface.

13. A method of forming a back barrier region in a high electron mobility transistor (HEMT), the HEMT having at least one design location for a source, a gate, and a drain of the HEMT, the method comprising:
depositing a buffer layer over a substrate;
depositing a barrier layer over the buffer layer to form a heterojunction; and
implanting fluorine ions into the buffer layer to form at least one back barrier region under the at least one design location for the gate.

14. The method of claim 13, the implanting includes implanting the fluorine ions to establish a peak fluorine concentration located in the buffer layer adjacent to the heterojunction.

15. The method of claim 13, the depositing of the buffer layer includes epitaxial crystal buffer layer growing of approximately 2 micrometers of unintentionally doped gallium nitride (GaN) and the depositing of the barrier layer includes epitaxial crystal barrier layer growing of approximately 24 nanometers of unintentionally doped aluminum gallium nitride (AlGaN).

16. The method of claim 13, the implanting includes implanting Fluorine-19 ions that have been imparted with an energy and at a dose substantially equivalent to 50 kilo electron Volts and 10¹² ions per square centimeter.

17. The method of claim 13, the depositing of the buffer layer includes growing the buffer layer over at least one of a sapphire substrate, a silicon (111) substrate, a silicon carbide (SiC) substrate, an aluminum nitride (AlN) substrate, or a Gallium Nitride (GaN) substrate.

18. The method of claim 13, the depositing of the buffer layer includes growing the buffer layer over the substrate having a Gallium Nitride (GaN) nucleation layer or an Aluminum Nitride (AlN) nucleation layer.

19. The method of claim 13, further comprising:
incorporating fluorine ions within the barrier layer to form an enhancement mode HEMT.

20. The method of claim 13, further comprising:
forming a low density drain region of fluorine adjacent to a design location of the gate and between the design location of the gate and a design location of the drain.

21. The method of claim 20, the implanting includes implanting the fluorine ions into the buffer layer to form the back barrier region under the design location of the gate and reaching to a region under a design location of the source.

22. An enhancement mode high electron mobility transistor (HEMT), comprising:
a buffer layer;
a barrier layer disposed over the buffer layer at an interface of the barrier layer and the buffer layer;
at least one fluorine blocking region disposed within the buffer layer and extending across a portion of the heterojunction; and
at least one fluorine treated region in the barrier layer.

23. The enhancement mode HEMT of claim 23, the at least one fluorine blocking region comprises a peak fluorine concentration located in the buffer layer adjacent to the interface.

24. The enhancement mode HEMT of claim 23, the at least one fluorine treated region comprises a low density drain region of fluorine adjacent to a design location of a gate and between the design location of the gate and a design location of a drain of the HEMT.

25. The enhancement mode HEMT of claim 23, the at least one fluorine treated region comprises a region of fluorine disposed within the barrier and below the design location of the gate.

26. The enhancement mode HEMT of claim 23, the at least one fluorine treated region comprises a region of fluorine implanted by at least one of a fluorine plasma treatment or low energy ion implantation.
